(19) United States
(12) Patent Application Publication
(10) Pub. No.: US 2020/0066993 A1
(43) Pub. Date: Feb. 27, 2020

(54) POLYMERIC CHARGE TRANSFER LAYER AND ORGANIC ELECTRONIC DEVICE COMPRISING THE SAME

(71) Applicants: DOW GLOBAL TECHNOLOGIES LLC, Midland, MI (US); ROHM AND HAAS ELECTRONIC MATERIALS LLC, Marlborough, MA (US); ROHM AND HAAS ELECTRONIC MATERIALS KOREA LTD., Chungcheongnam-do (KR)

(72) Inventors: Yang LI, Shanghai (CN); Minrong ZHU, Shanghai (CN); Jichang FENG, Shanghai (CN); Shaoguang FENG, Shanghai (CN); Chun LIU, Midland, MI (US); Yuchen LIU, Shanghai (CN); David Dayton DEVORE, Midland, MI (US); Peter TREFONAS, III, Marlborough, MA (US); Hong Yeop NA, Gyeonggi-do (KR); Robert WRIGHT, Freeport, TX (US); Liam Patrick SPENCER, Freeport, TX (US); John William KRAMER, Midland, MI (US); Anatoliy SOKOLOV, Midland, MI (US); Emad AQAD, Marlborough, MA (US)

(21) Appl. No.: 16/344,111

(22) PCT Filed: Nov. 7, 2016
(86) PCT No.: PCT/CN2016/104856

§ 371 Date: Apr. 23, 2019

(51) Int. Cl. H01L 51/00

(52) U.S. Cl. CPC H01L 51/0043; H01L 51/0038; H01L 51/5056; H01L 51/006; H01L 51/0072

(57) ABSTRACT

Polymeric charge transfer layer compositions suitable for organic layers of electronic devices that show reduced driving voltage and increased luminous efficiency.

### FIELD OF THE DISCLOSURE

The present disclosure relates to a polymeric charge transfer layer composition comprising a polymer comprising, as polymerized units, at least one carbazole-based Monomer A. The present disclosure further relates to an organic electronic device, especially, a light emitting device containing the polymeric charge transfer layer.

### INTRODUCTION

Organic electronic devices are devices that carry out electrical operations using at least one organic material. They are endowed with advantages such as flexibility, low power consumption, and relatively low cost over conventional inorganic electronic devices. Organic electronic devices usually include organic light emitting devices, organic solar cells, organic memory devices, organic sensors, organic thin film transistors, and power generation and storage devices such as organic batteries, fuel cells, and organic supercapacitors. Such organic electronic devices are prepared from hole injection or transportation materials, electron injection or transportation materials, or light emitting materials.

A typical organic light emitting device is an organic light emitting diode (OLED) having a multi-layer structure, and typically includes an anode, and a metal cathode. Sandwiched between the anode and the metal cathode are several organic layers such as a hole injection layer (HIL), a hole transfer layer (HTL), an emitting layer (EML), an electron transfer layer (ETL), and an electron injection layer (EIL). New material discovery for ETL and HTL in OLEDs have been targeted to improve device performance and lifetime. In the case of HTL layer, as a typical polymeric charge transfer layer, the process by which the layer is deposited is critical for its end-use application. Methods for depositing HTL layer, in small display applications, involve evaporation of a small organic compound with a fine metal mask to direct the deposition. In the case of large displays, this approach is not practical from a material usage and high throughput perspective. With these findings in mind, new processes are needed to deposit HTLs that satisfy these challenges, and which can be directly applied to large display applications.

One approach that appears promising is a solution process which involves the deposition of a small molecule HTL material attached with crosslinking or polymerization moiety. Solution process based methods include spin-coating, inkjet printing, slot-die coating and screen printing which are well-known in the art. There have been extensive efforts in this area, along these lines; however, these approaches have their own shortcomings. In particular, the mobility of the charges in the HTL becomes reduced, as a result of crosslinking or polymerization chemistry. In some cases, this could lead to reduced device lifetime.

Therefore, it is still desired to provide new polymeric charge transfer layer compositions for organic electronic devices, specifically for organic light emitting devices, organic solar cells, or organic memory devices with improved hole mobility and device lifetime.

### SUMMARY OF THE DISCLOSURE

The present disclosure provides a polymeric charge transfer layer composition comprising a polymer comprising, as polymerized units, at least one carbazole-based Monomer A, and optionally at least one Monomer B.

Monomer A has the following Structure A:

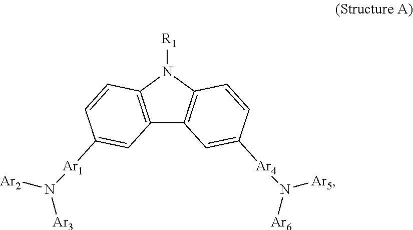

Monomer B has the following Structure B:

R₂—CH₂O—R₃ (Structure B).

Ar₁ to Ar₆ are each independently selected from a substituted or unsubstituted aromatic moiety, and a substituted or unsubstituted heteroaromatic moiety.

R₁, R₂ and R₃ are each independently selected from the group consisting of hydrogen, deuterium (“D”), a substituted or unsubstituted hydrocarbyl, a substituted or unsubstituted heterohydrocarbyl, a halogen, a cyano, a substituted or unsubstituted aryl, and a substituted or unsubstituted heteroaryl.

The present disclosure further provides an organic light emitting device and an organic electronic device comprising the polymeric charge transfer layer.

### DETAILED DESCRIPTION OF THE DISCLOSURE

The polymeric charge transfer layer composition of the present disclosure comprises a polymer and an optional p-dopant. The polymer comprises, as polymerized units, at least one carbazole-based Monomer A, and optionally at least one Monomer B.

The Polymer

The polymer comprises Monomer A having the following Structure A:

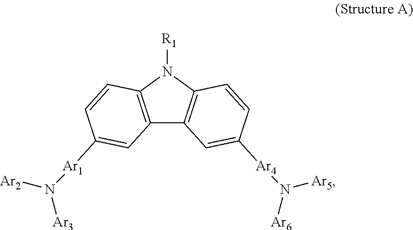

optional Monomer B having the following Structure B:

R₂—CH₂O—R₃ (Structure B);

wherein Ar₁ to Ar₆ are each independently selected from a substituted or unsubstituted aromatic moiety, and a substituted or unsubstituted heteroaromatic moiety.

Suitable examples of Ar₁ to Ar₆ include

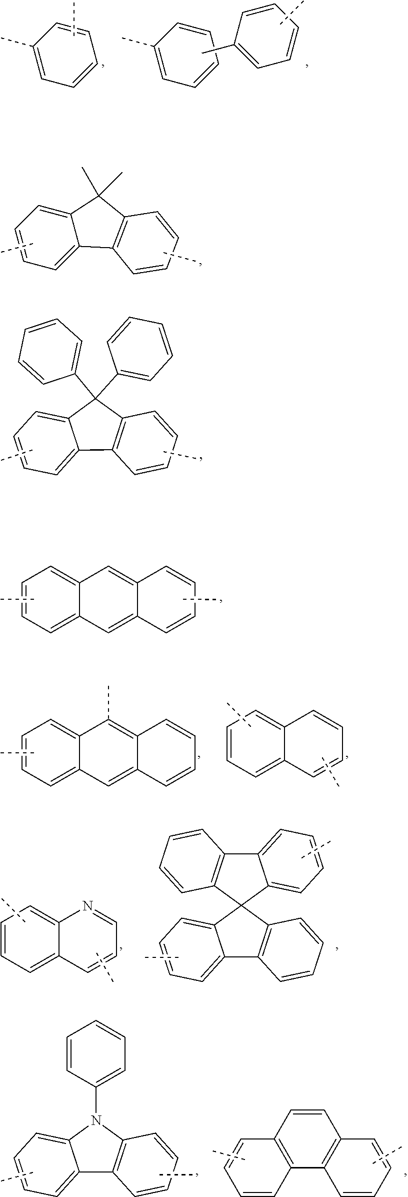

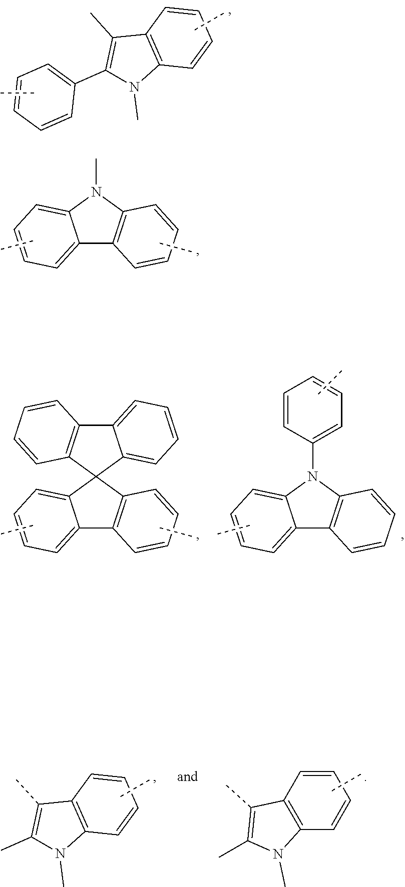

R₁ to R₃ are each independently selected from the group consisting of hydrogen; deuterium (“D”); a substituted or unsubstituted hydrocarbyl such as C₁-C₁₀₀ hydrocarbyl, C₃-C₁₀₀ hydrocarbyl, C₁₀-C₁₀₀ hydrocarbyl, C₂₀-C₁₀₀ hydrocarbyl, and C₃₀-C₁₀₀ hydrocarbyl; a substituted or unsubstituted heterohydrocarbyl such as C₁-C₁₀₀ heterohydrocarbyl, C₃-C₁₀₀ heterohydrocarbyl, C₁₀-C₁₀₀ heterohydrocarbyl, C₂₀-C₁₀₀ heterohydrocarbyl, and C₃₀-C₁₀₀ heterohydrocarbyl; a halogen, a cyano, a substituted or unsubstituted aryl such as C₅-C₁₀₀ aryl, C₆-C₁₀₀ aryl, C₁₀-C₁₀₀ aryl, C₂₀-C₁₀₀ aryl, and C₃₀-C₁₀₀ aryl; and a substituted or unsubstituted heteroaryl such as C₅-C₁₀₀ heteroaryl, C₆-C₁₀₀ heteroaryl, C₁₀-C₁₀₀ heteroaryl, C₂₀-C₁₀₀ heteroaryl, and C₃₀-C₁₀₀ heteroaryl.

Preferably, R₁ to R₃ each independently has the functional group represented by Structure I, so that the polymer obtained therefrom has a crosslinked structure.

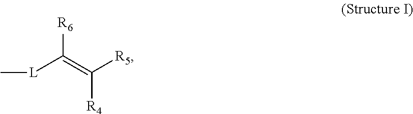

wherein R₄ to R₆ are each independently selected from the group consisting of hydrogen, deuterium, a substituted or unsubstituted C₁-C₅₀ hydrocarbyl, a substituted or unsubstituted C₁-C₅₀ heterohydrocarbyl, a halogen, a cyano, a substituted or unsubstituted C₆-C₅₀ aryl, and a substituted or unsubstituted C₄-C₅₀ heteroaryl.

L is selected from the group consisting of a covalent bond; —O—; -alkylene-; -arylene-; -alkylene-arylene-; -arylene-alkylene-; —O-alkylene-; —O-arylene-; —O-alkylene-arylene-; —O-alkylene-O—; —O-alkylene-O-alkylene-O—; —O-arylene-O—; —O-alkylene-arylene-O—; —O—(CH₂CH₂—O)ₙ—, wherein n is an integer from 2 to 20; —O-alkylene-O-alkylene-; —O-alkylene-O-arylene-; —O-arylene-O—; —O-arylene-O-alkyene-; and —O-arylene-O-arylene.

Preferably, L is -alkylene-, -arylene-, -alkylene-arylene-, -arylene-alkylene-, or a covalent bond. More preferably, L is -arylene-, -arylene-alkylene-, or a covalent bond.

Suitable examples of Structure I include the following Structures (I-1) through (I-12):

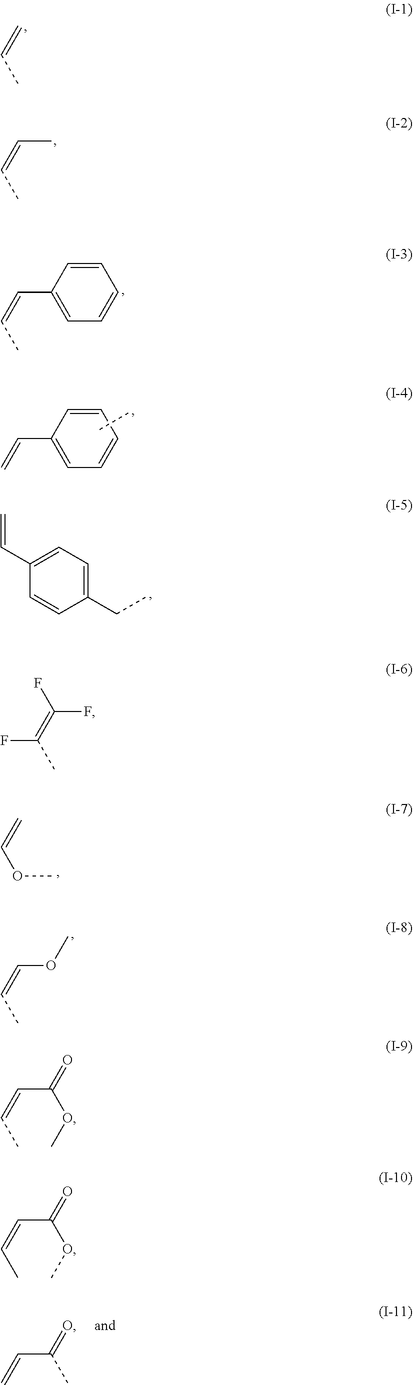

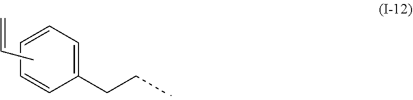

Preferably, Structure I is selected from Structures (1-4), (I-5), (I-11), and (I-12).

In one embodiment, Monomer A is selected from the following Compounds (A1) through (A9):

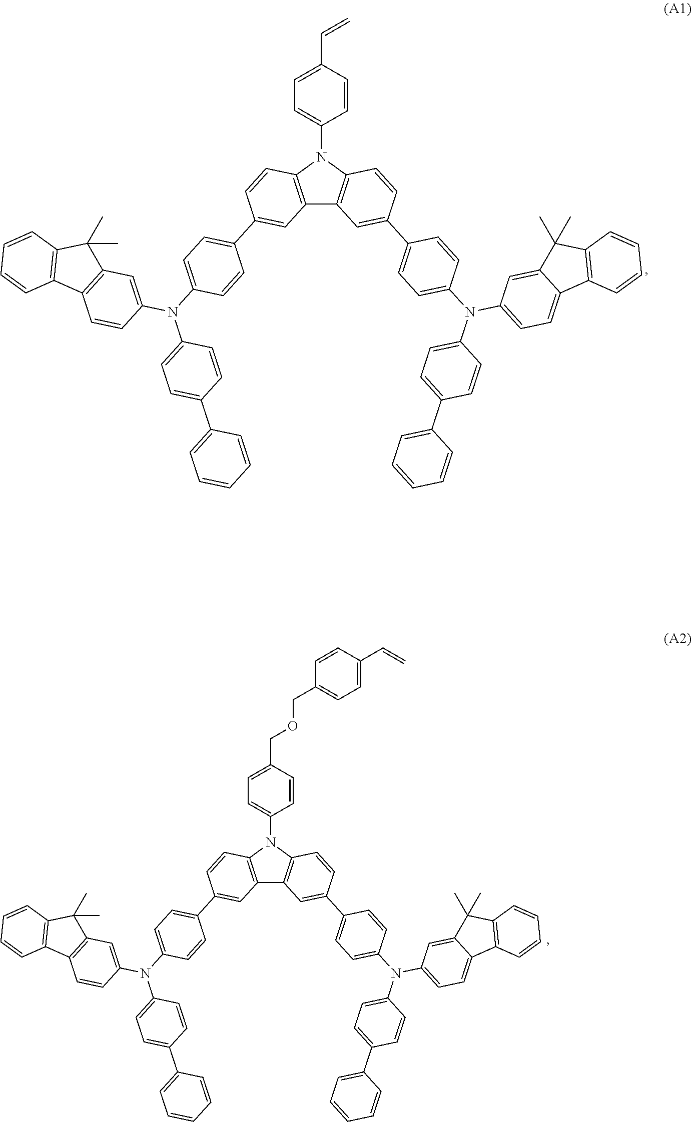 [SMILES: C=Cc1ccc(-n2c3ccc(-c4ccc(N(c5ccc(-c6ccccc6)cc5)c5ccc6c(c5)C(C)(C)c5ccccc5-6)cc4)cc3c3cc(-c4ccc(N(c5ccc(-c6ccccc6)cc5)c5ccc6c(c5)C(C)(C)c5ccccc5-6)cc4)ccc32)cc1 ; C=Cc1ccc(COCc2ccc(-n3c4ccc(-c5ccc(N(c6ccc(-c7ccccc7)cc6)c6ccc7c(c6)C(C)(C)c6ccccc6-7)cc5)cc4c4cc(-c5ccc(N(c6ccc(-c7ccccc7)cc6)c6ccc7c(c6)C(C)(C)c6ccccc6-7)cc5)ccc43)cc2)cc1]

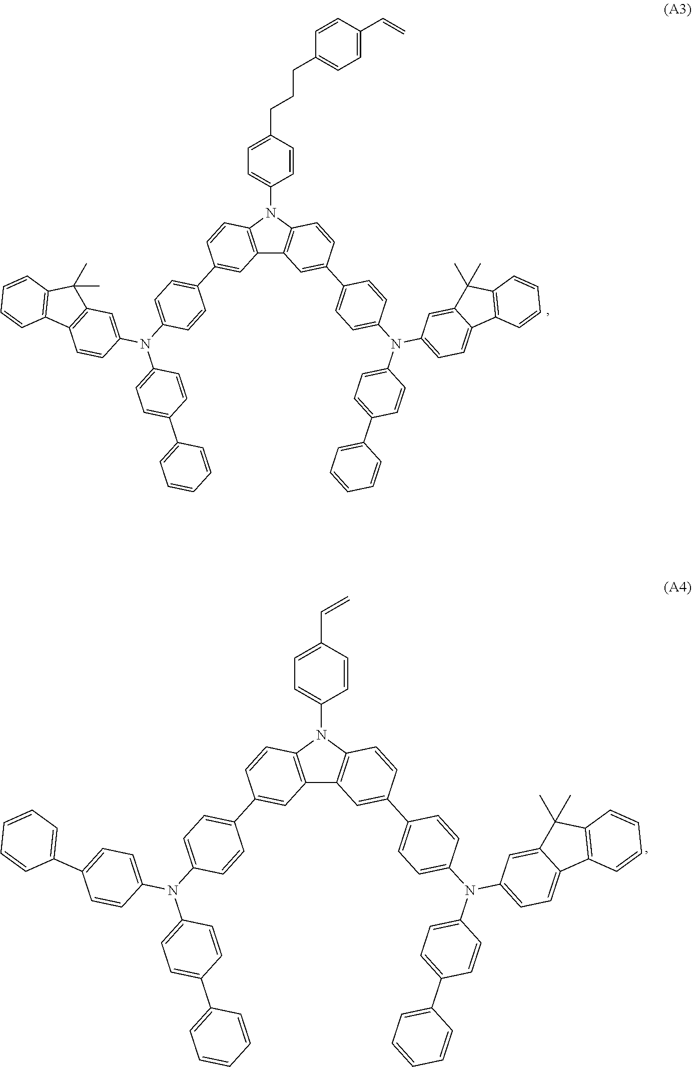 [SMILES: C=Cc1ccc(CCCc2ccc(-n3c4ccc(-c5ccc(N(c6ccc(-c7ccccc7)cc6)c6ccc7c(c6)C(C)(C)c6ccccc6-7)cc5)cc4c4cc(-c5ccc(N(c6ccc(-c7ccccc7)cc6)c6ccc7c(c6)C(C)(C)c6ccccc6-7)cc5)ccc43)cc2)cc1 ; C=Cc1ccc(-n2c3ccc(-c4ccc(N(c5ccc(-c6ccccc6)cc5)c5ccc(-c6ccccc6)cc5)cc4)cc3c3cc(-c4ccc(N(c5ccc(-c6ccccc6)cc5)c5ccc6c(c5)C(C)(C)c5ccccc5-6)cc4)ccc32)cc1]

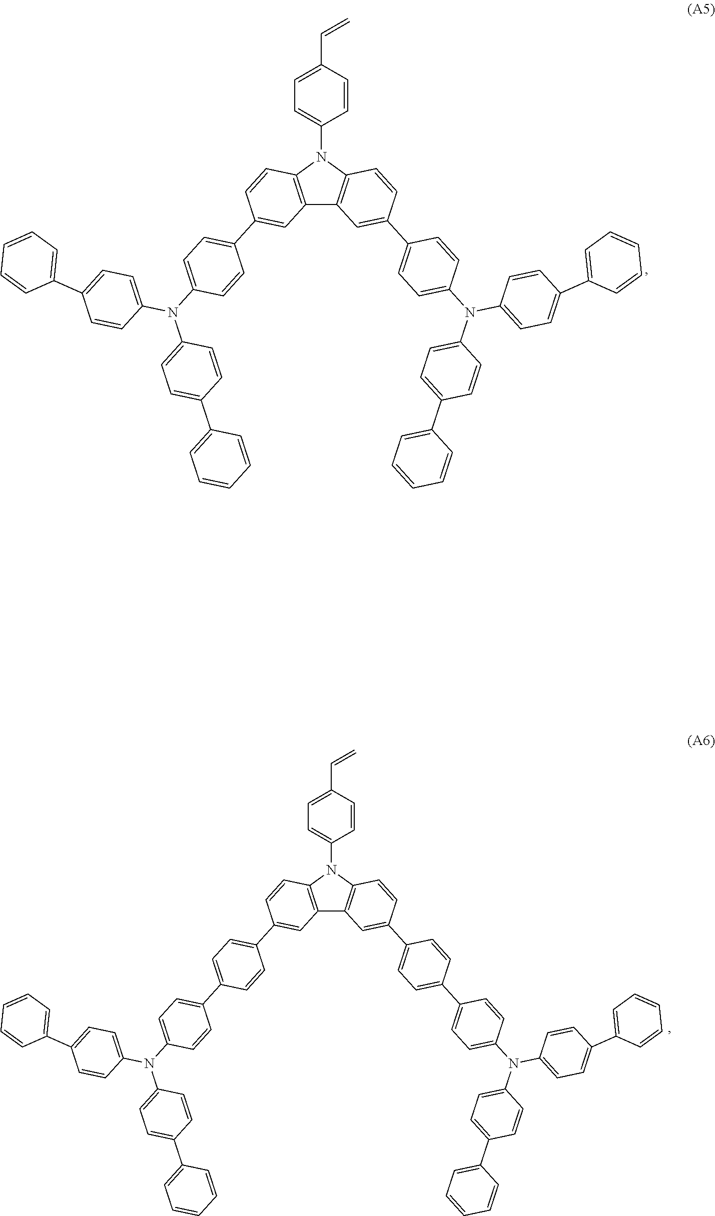 [SMILES: C=Cc1ccc(-n2c3ccc(-c4ccc(N(c5ccc(-c6ccccc6)cc5)c5ccc(-c6ccccc6)cc5)cc4)cc3c3cc(-c4ccc(N(c5ccc(-c6ccccc6)cc5)c5ccc(-c6ccccc6)cc5)cc4)ccc32)cc1 ; C=Cc1ccc(-n2c3ccc(-c4ccc(-c5ccc(N(c6ccc(-c7ccccc7)cc6)c6ccc(-c7ccccc7)cc6)cc5)cc4)cc3c3cc(-c4ccc(-c5ccc(N(c6ccc(-c7ccccc7)cc6)c6ccc(-c7ccccc7)cc6)cc5)cc4)ccc32)cc1]

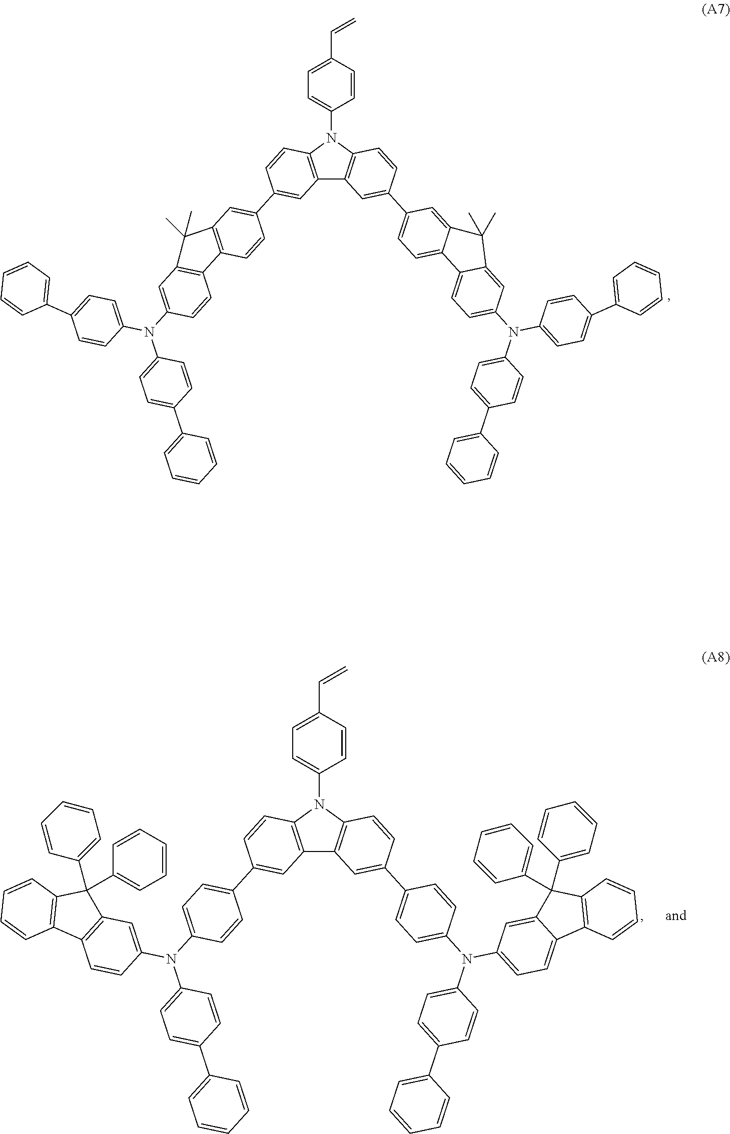 [SMILES: C=Cc1ccc(-n2c3ccc(-c4ccc5c(c4)C(C)(C)c4cc(N(c6ccc(-c7ccccc7)cc6)c6ccc(-c7ccccc7)cc6)ccc4-5)cc3c3cc(-c4ccc5c(c4)C(C)(C)c4cc(N(c6ccc(-c7ccccc7)cc6)c6ccc(-c7ccccc7)cc6)ccc4-5)ccc32)cc1 ; C=Cc1ccc(-n2c3ccc(-c4ccc(N(c5ccc(-c6ccccc6)cc5)c5ccc6c(c5)C(c5ccccc5)(c5ccccc5)c5ccccc5-6)cc4)cc3c3cc(-c4ccc(N(c5ccc(-c6ccccc6)cc5)c5ccc6c(c5)C(c5ccccc5)(c5ccccc5)c5ccccc5-6)cc4)ccc32)cc1]

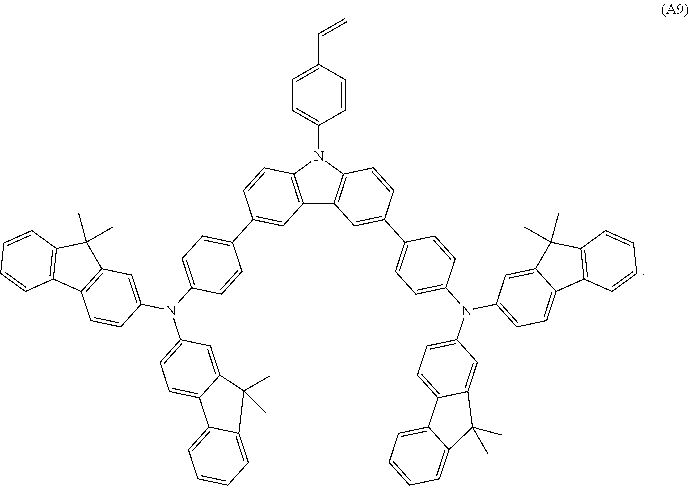 [SMILES: C=Cc1ccc(-n2c3ccc(-c4ccc(N(c5ccc6c(c5)C(C)(C)c5ccccc5-6)c5ccc6c(c5)C(C)(C)c5ccccc5-6)cc4)cc3c3cc(-c4ccc(N(c5ccc6c(c5)C(C)(C)c5ccccc5-6)c5ccc6c(c5)C(C)(C)c5ccccc5-6)cc4)ccc32)cc1]

Monomer A useful in the present disclosure has a molecular weight of from 500 g/mole to 28,000 g/mole, preferably from 800 g/mole to 14,000 g/mole, preferably from 1,000 g/mole to 7,000 g/mole.

In one embodiment, Monomer A is further purified through ion exchange beads to remove cationic and anionic impurities, such as metal ion, sulfate ion, formate ion, oxalate ion and acetate ion. The purity of Monomer A is equal to or above 99%, equal to or above 99.4%, or even equal to or above 99.5%. The said purify is achieved through well-known methods in the art including, for example, fractionation, sublimation, chromatography, crystallization and precipitation methods.

Monomer A is present in the present disclosure in an amount of at least 54% by mole, 70% by mole or more, 80% by mole or more, 90% by mole or more, or even 100% by mole, based on the total moles of all monomers in the polymer. Preferably, the polymer comprises 100% by mole of Monomer A based on the total moles of all monomers in the composition.

Monomer B is present in the present disclosure in an amount of at most 46% by mole, or 30% by mole or less, 20% by mole or less, 10% by mole or less, or even 5% by mole or less, based on the total moles of all monomers in the polymer.

In one embodiment, Monomer B is selected from the following Compounds (B1) through (B9):

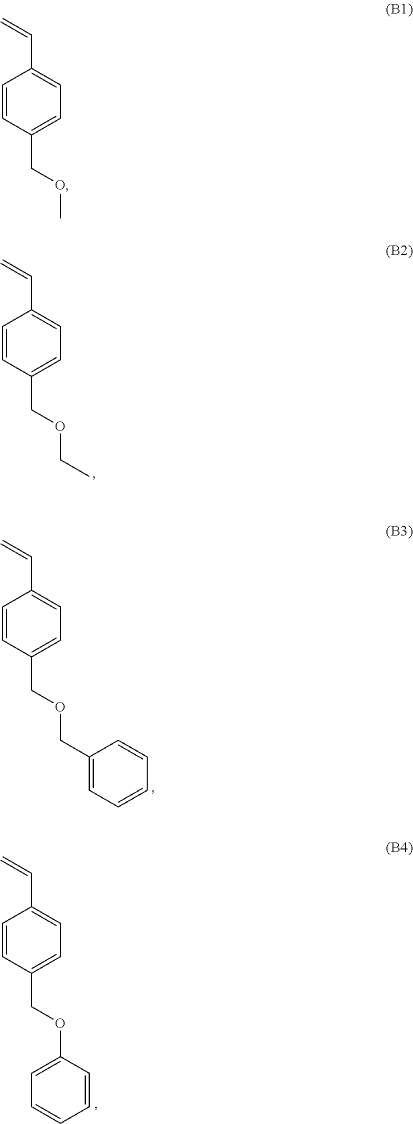 [SMILES: C=Cc1ccc(COC)cc1 ; C=Cc1ccc(COCC)cc1 ; C=Cc1ccc(COCc2ccccc2)cc1 ; C=Cc1ccc(COc2ccccc2)cc1]

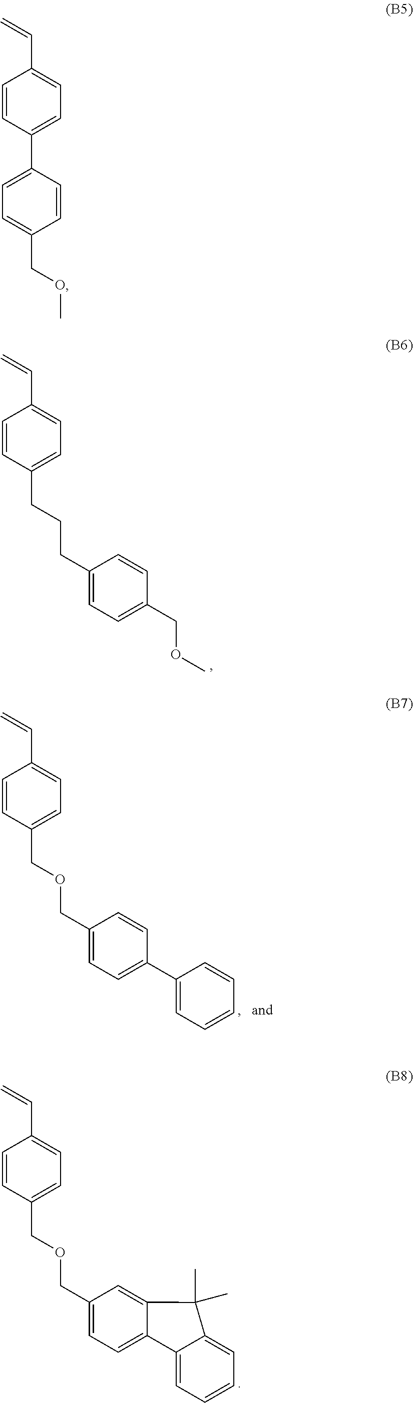 [SMILES: C=Cc1ccc(-c2ccc(COC)cc2)cc1 ; C=Cc1ccc(CCCc2ccc(COC)cc2)cc1 ; C=Cc1ccc(COCc2ccc(-c3ccccc3)cc2)cc1 ; C=Cc1ccc(COCc2ccc3c(c2)C(C)(C)c2ccccc2-3)cc1]

P-Dopant

Optionally, the polymer may be blended with one or more p-dopants to make the polymeric charge transfer layer composition. P-dopants are selected from ionic compounds including trityl salts, ammonium salts, iodonium salts, tropylium salts, imidazolium salts, phosphonium salts, oxonium salts, and mixtures thereof. Preferably, the ionic compounds are selected from trityl borates, ammonium borates, iodonium borates, tropylium borates, imidazolium borates, phosphonium borates, oxonium borates, and mixtures thereof. Suitable examples of p-dopants used in the present disclosure include the following Compounds (p-1) through (p-13):

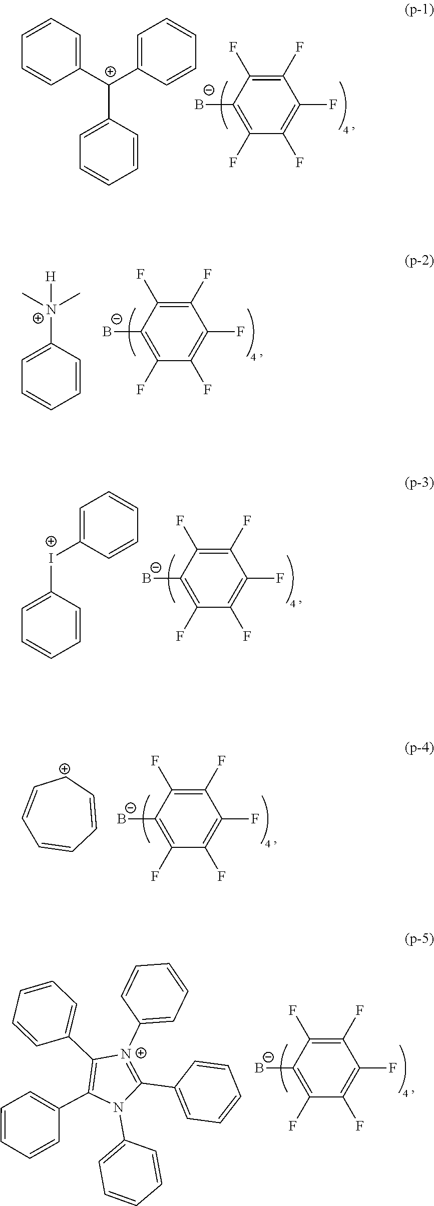

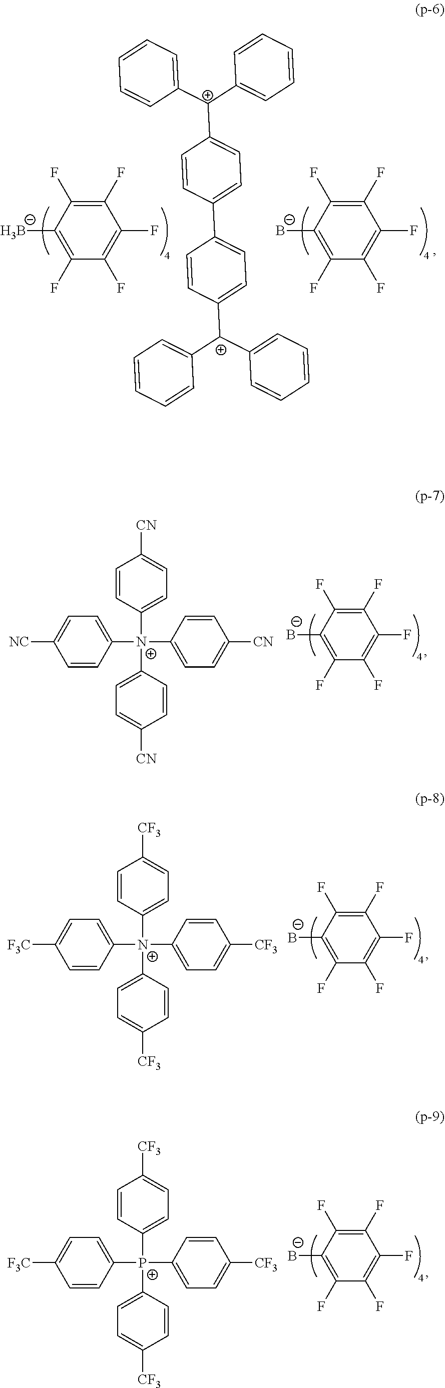

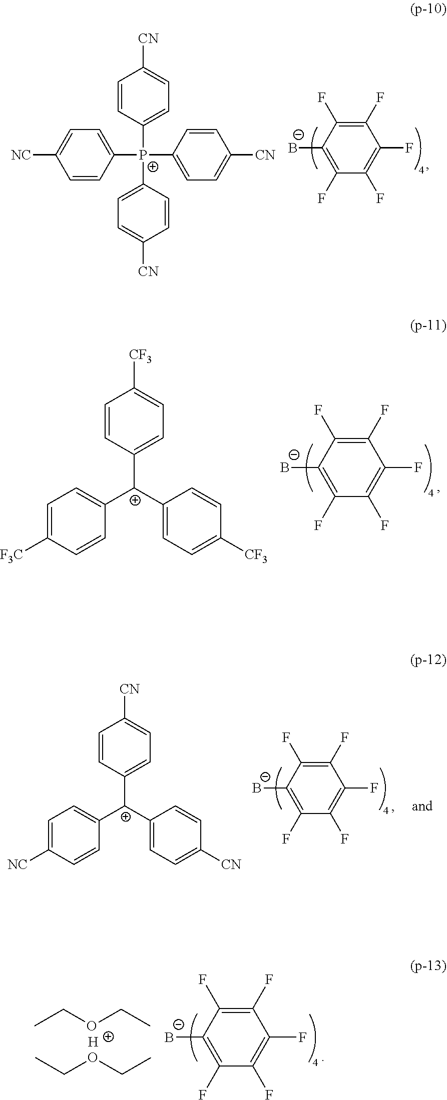

Preferably, the p-dopant is the following compound (p-1):

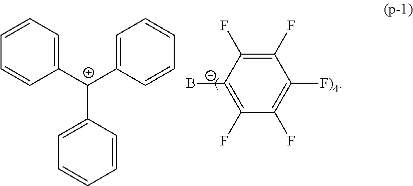

The p-dopant is present in the present disclosure at an amount of 1% by weight or more, 3% by weight or more, 5% by weight or more, or even 7% by weight or more, and at the same time, 20% by weight or less, 15% by weight or less, 12% by weight or less, or even 10% by weight or less, based on the total weight of the polymeric charge transfer layer composition.

Organic Charge Transfer Film

The present invention provides an organic charge transfer film which is further directed to an organic charge transporting film and a process for producing it by coating the polymeric charge transfer layer composition on a surface, preferably another organic charge transporting film, and Indium-Tin-Oxide (ITO) glass or a silicon wafer. The film is formed by coating the composition on a surface, baking at a temperature from 50 to 150° C. (preferably 80 to 120° C.), preferably for less than five minutes, followed by thermal cross-linking at a temperature from 120 to 280° C.; preferably at least 140° C., preferably at least 160° C., preferably at least 170° C.; preferably no greater than 230° C., preferably no greater than 215° C.

Preferably, the thickness of the polymer films produced according to this invention is from 1 nm to 100 microns, preferably at least 10 nm, preferably at least 30 nm, preferably no greater than 10 microns, preferably no greater than 1 micron, preferably no greater than 300 nm. The spin-coated film thickness is determined mainly by the solid contents in solution and the spin rate. For example, at a 2000 rpm spin rate, 2, 5, 8 and 10 wt % polymer resin formulated solutions result in the film thickness of 30, 90, 160 and 220 nm, respectively. The wet film shrinks by 5% or less after baking and cross-linking.

Organic Electronic Device

The present invention provides a method of making an organic electronic device. The method comprises providing the polymeric charge transfer layer composition of the present invention, and dissolving or dispersing the polymeric charge transfer layer composition in any of the organic solvents known or proposed to be used in the fabrication of an organic electronic device by solution process. Such organic solvents include tetrahydrofuran (THF), cyclohexanone, chloroform, 1,4-dioxane, acetonitrile, ethyl acetate, tetralin, chlorobenzene, toluene, xylene, anisole, mesitylene, tetralone, and mixtures thereof. The resulted polymeric charge transfer layer solution was filtered through a membrane or a filter to remove particles larger than 50 nm.

The polymeric charge transfer layer solution is then deposited over a first electrode. The deposition may be performed by any of various types of solution processing techniques known or proposed to be used for fabricating organic electronic devices. For example, the polymeric charge transfer layer solution can be deposited using a printing process, such as inkjet printing, nozzle printing, offset printing, transfer printing, or screen printing; or for example, using a coating process, such as spray coating, spin coating, or dip coating. After deposition of the solution, the solvent is removed, which may be performed by using conventional method such as vacuum drying and/or heating.

The polymeric charge transfer layer solution is further cross-linked to form the polymeric charge transfer layer. Cross-linking may be performed by exposing the layer solution to heat and/or actinic radiation, including UV light, gamma rays, or x-rays. Cross-linking may be carried out in the presence of an initiator that decomposed under heat or irradiation to produce free radicals or ions that initiate the cross-linking reaction. The cross-linking may be performed in-situ during the fabrication of a device. After cross-linking, the polymeric charge transfer layer made thereof is preferably free of residual moieties which are reactive or decomposable with exposure to light, positive charges, negative charges or excitons.

The process of solution deposition and cross-linking can be repeated to create multiple layers.

Preferably, an OLED contains the following layers in contact with each other in order as follows: a substrate, a first conductive layer, optionally one or more hole injection layers, one or more hole transport layers, optionally one or more electron blocking layers, an emitting layer, optionally one or more hole blocking layers, optionally one or more electron transport layer, an electron injection layer, and a second conductive layer.

In one embodiment, the polymeric charge transfer layer is used as the hole transport layer in the OLED. The first conductive layer is used as an anode and in general is a transparent conducting oxide, for example, fluorine-doped tin oxide, antimony-doped tin oxide, zinc oxide, aluminum-doped zinc oxide, indium tin oxide, metal nitride, metal selenide and metal sulfide. It is preferred that the material has a good thin film-forming property to ensure sufficient contact between the first conductive layer and hole transport layer to promote hole injection under low voltage and provide better stability. Typically, the hole transport layer is in contact with the emitting layer. Optionally, an electron blocking layer may be placed between the hole transport layer and the emitting layer. The emitting layer plays a very important role in the whole structure of the light emitting device. In addition to determining the color of the device, the emitting layer also has an important impact on the luminance efficiency in a whole. Common emitter materials can be classified as fluorescent and phosphorescent depending on the light emitting mechanism. The second conductive layer is a cathode and comprises a conductive material. For example, the material of the cathode can be a metal such as aluminum and calcium, a metal alloy such as magnesium/silver and aluminum/lithium, and any combinations thereof. Moreover, an extremely thin film of lithium fluoride as an electron injection layer may be optionally placed between the cathode and the emitting layer. Lithium fluoride can effectively reduce the energy barrier of injecting electrons from the cathode to the emitting layer. Optionally, an electron transport layer may be placed between the emitting layer and the electron injection layer. Optionally, a hole blocking layer may be placed between the electron transporting layer and the emitting layer.

### Definitions

The term “organic electronic device” refers to a device that carries out an electrical operation with the presence of organic materials. Specific examples of organic electronic devices include organic photovoltaics; organic sensors; organic thin film transistors; organic memory devices; organic field effect transistors; and organic light emitting devices such as OLED devices; and power generation and storage devices such as organic batteries, fuel cells, and organic super capacitors.

The term “organic light emitting device” refers to a device that emits light when an electrical current is applied across two electrodes. Specific example includes light emitting diodes.

The term “p-dopant” refers to an additive that can increase the hole conductivity of a charge transfer layer.

The term “polymeric charge transfer layer” refers to a polymeric material that can transport charge, either holes or electrons. Specific example includes a hole transport layer.

The term “anode” typically refers to a metal, a metal oxide, a metal halide, an electro-conductive polymer, and combinations thereof, that injects holes into either the emitting layer or a layer that is located between the emitting layer and the anode, such as a hole injection layer or a hole transport layer. The anode is disposed on a substrate.

The term “blocking layer” refers to a layer providing a barrier that significantly inhibits transport of one type of charge carriers and/or excitons through the device, without suggesting that the layer necessarily completely blocks all charge carriers and/or excitons. The presence of such a blocking layer in a device may result in higher efficiencies as compared to a similar device lacking a blocking layer. Also, a blocking layer may be used to confine emission to a desired region of an OLED. Blocking layers, when present, are generally present on either side of the emitting layer.

Electron blocking may be accomplished in various ways including, for example, by using a blocking layer that has a LUMO energy level that is significantly higher than the LUMO energy level of the emissive layer. The greater difference in LUMO energy levels results in better electron blocking properties. Suitable materials for use in the blocking layer are dependent upon the material of emissive layer. A layer that primarily performs electron blocking is an electron blocking layer (EBL). Electron blocking may occur in other layers, for example, a hole transport layer (HTL).

Hole blocking may be accomplished in various ways including, for example, by using a blocking layer that has a HOMO energy level that is significantly lower than the HOMO energy level of the emissive layer. The greater difference in HOMO energy levels results in better hole blocking properties. Suitable materials for use in the blocking layer are dependent upon the material of emissive layer. A layer that primarily performs hole blocking is a hole blocking layer (HBL). Hole blocking may occur in other layer, for example, an electron transport layer (ETL).

Blocking layers may also be used to block excitons from diffusing out of the emissive layer by using a blocking layer that has a triplet energy level that is significantly higher than the triplet energy level of the EML dopant or the EML host. Suitable materials for use in the blocking layer are dependent upon the material composition of emissive layer.

The term “cathode” typically refers to a metal, a metal oxide, a metal halide, an electroconductive polymer, or a combination thereof, that injects electrons into the emitting layer or a layer that is located between the emitting layer and the cathode, such as an electron injection layer or an electron transport layer.

The term “electron injection layer,” or “EIL,” and the like, refers to a layer which improves injection of electrons injected from the cathode into the electron transport layer.

The term “emitting layer” and the like, refers to a layer located between electrodes (anode and cathode) and when placed in an electric field supports the emission of light by the recombination of holes with electrons, the emitting layer being the primary light-emitting source. The emitting layer typically consists of host and emitter. The host material could be preferentially hole or electron transporting or can be similarly transporting of both holes and electrons, and may be used alone or by combination of two or more host materials. The opto-electrical properties of the host material may differ to which type of emitter (Phosphorescent or Fluorescent) is used. The emitter is a material that undergoes radiative emission from an excited state. The excited state can be generated, for example, by charges on the emitter molecule or by energy transfer from the excited state of another molecule.

The term “electron transport layer,” or “ETL,” and the like, refers to a layer made from a material, which exhibits properties including high electron mobility for efficiently transporting electrons injected from the cathode or the EIL and favorable injection of those electrons into the hole blocking layer or the emitting layer.

The term “hole injection layer,” or “HIL,” and the like, refers to a layer for efficiently transporting or injecting holes from the anode into the emissive layer, the electron blocking layer, or more typically into the hole transport layer. Multiple hole injection layers may be used to accomplish hole injection from the anode to the hole transporting layer, electron blocking layer or the emitting layer.

The term “hole transport layer.” or “HTL,” and the like, refers to a layer made from a material, which exhibits properties including high hole mobility for efficiently transporting holes injected from the anode or the HIL and favorable injection of those holes into the electron blocking layer or the emitting layer.

The term “aromatic moiety” refers to an organic moiety derived from aromatic hydrocarbyl by deleting at least one hydrogen atom therefrom. An aromatic moiety may be a monocyclic and/or fused ring system, each ring of which suitably contains from 4 to 7, preferably from 5 or 6 atoms. Structures wherein two or more aromatic moieties are combined through single bond(s) are also included. Specific examples include phenyl, naphthyl, biphenyl, anthryl, indenyl, fluorenyl, benzofluorenyl, phenanthryl, triphenylenyl, pyrenyl, perylenyl, chrysenyl, naphtacenyl, and fluoranthenyl. The naphthyl may be 1-naphthyl or 2-naphthyl, the anthryl may be 1-anthryl, 2-anthryl or 9-anthryl, and the fluorenyl may be any one of 1-fluorenyl, 2-fluorenyl, 3-fluorenyl, 4-fluorenyl and 9-fluorenyl.

The term “heteroaromatic moiety” refers to an aromatic moiety, in which at least one carbon atom or CH group or CH₂ group is substituted with a heteroatom or a chemical group containing at least one heteroatom. The heteroaromatic moiety may be a 5- or 6-membered monocyclic heteroaryl, or a polycyclic heteroaryl which is fused with one or more benzene ring(s), and may be partially saturated. The structures having one or more heteroaromatic moieties bonded through a single bond are also included. Specific examples include monocyclic heteroaryl groups, such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl; polycyclic heteroaryl groups, such as benzofuranyl, fluoreno[4,3-b]benzofuranyl, benzothiophenyl, fluoreno[4,3-b]benzothiophenyl, isobenzofuranyl, benzimidazolyl, benzothiazolyl, benzisothiazolyl, benzisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenanthridinyl and benzodioxolyl.

The term “hydrocarbyl” refers to a chemical group containing only hydrogen and carbon atoms.

The term “substituted hydrocarbyl” refers to a hydrocarbyl in which at least one hydrogen atom is substituted with a heteroatom or a chemical group containing at least one heteroatom.

The term “heterohydrocarbyl” refers to a chemical group containing hydrogen and carbon atoms, and wherein at least one carbon atom or CH group or CH₂ group is substituted with a heteroatom or a chemical group containing at least one heteroatom.

The term “substituted heterohydrocarbyl” refers to a heterohydrocarbyl in which at least one hydrogen atom is substituted with a heteroatom or a chemical group containing at least one heteroatom.

The term “aryl” refers to an organic radical derived from aromatic hydrocarbyl by deleting one hydrogen atom therefrom. An aryl group may be a monocyclic and/or fused ring system, each ring of which suitably contains from 4 to 7, preferably from 5 or 6 atoms. Structures wherein two or more aryl groups are combined through single bond(s) are also included. Specific examples include phenyl, naphthyl, biphenyl, anthryl, indenyl, fluorenyl, benzofluorenyl, phenanthryl, triphenylenyl, pyrenyl, perylenyl, chrysenyl, naphtacenyl, and fluoranthenyl. The naphthyl may be 1-naphthyl or 2-naphthyl, the anthryl may be 1-anthryl, 2-anthryl or 9-anthryl, and the fluorenyl may be any one of 1-fluorenyl, 2-fluorenyl, 3-fluorenyl, 4-fluorenyl and 9-fluorenyl.

The term “substituted aryl” refers to an aryl in which at least one hydrogen atom is substituted with a heteroatom or a chemical group containing at least one heteroatom.

The term “heteroaryl” refers to an aryl group, in which at least one carbon atom or CH group or CH₂ group is substituted with a heteroatom or a chemical group containing at least one heteroatom. The heteroaryl may be a 5- or 6-membered monocyclic heteroaryl or a polycyclic heteroaryl which is fused with one or more benzene ring(s), and may be partially saturated. The structures having one or more heteroaryl group(s) bonded through a single bond are also included. The heteroaryl groups may include divalent aryl groups of which the heteroatoms are oxidized or quarternized to form N-oxides, quaternary salts, or the like. Specific examples include, but are not limited to, monocyclic heteroaryl groups, such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl; polycyclic heteroaryl groups, such as benzofuranyl, fluoreno[4,3-b]benzofuranyl, benzothiophenyl, fluoreno[4,3-b]benzothiophenyl, isobenzofuranyl, benzimidazolyl, benzothiazolyl, benzisothiazolyl, benzisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenanthridinyl and benzodioxolyl; and corresponding N-oxides (for example, pyridyl N-oxide, quinolyl N-oxide) and quaternary salts thereof.

The term “substituted heteroaryl” refers to a heteroaryl in which at least one hydrogen atom is substituted with a heteroatom or a chemical group containing at least one heteroatom. Heteroatoms include O, N, P, P(═O), Si, B and S.

The term “monomer” refers to a compound containing one or more functional groups that is able to be polymerized into a polymer.

The term “polymer” refers to a polymeric compound prepared by polymerizing monomers, whether of the same or a different type. The generic term polymer thus embraces the term homopolymer (employed to refer to polymers prepared from only one type of monomer, with the understanding that trace amounts of impurities can be incorporated into and/or within the polymer structure), and the term copolymer as defined hereinafter.

The term “copolymer” refers to polymers prepared by the polymerization of at least two different types of monomers.

### Examples

The following examples illustrate embodiments of the present disclosure. All parts and percentages are by weight unless otherwise indicated.

All solvents and reagents are available from commercial vendors, for example, Sigma-Aldrich, TCI, and Alfa Aesar, and are used in the highest available purities, and/or when necessary, recrystallized before use. Dry solvents were obtained from in-house purification/dispensing system (hexane, toluene, and tetrahydrofuran), or purchased from Sigma-Aldrich. All experiments involving “water sensitive compounds” are conducted in “oven dried” glassware, under nitrogen atmosphere, or in a glovebox.

The following standard analytical equipment and methods are used in the Examples.

Gel Permeation Chromatography (GPC)

Gel permeation chromatography (GPC) is used to analysis the molecular weights of the polymers. 2 mg of HTL polymer was dissolved in 1 mL THF. The solution was filtrated through a 0.20 m polytetrafluoroethylene (PTFE) syringe filter and 50l of the filtrate was injected onto the GPC system. The following analysis conditions were used: Pump: Waters™ e2695 Separations Modules at a nominal flow rate of 1.0 mL/min; Eluent: Fisher Scientific HPLC grade THF (stabilized); Injector: Waters e2695 Separations Modules; Columns: two 5 am mixed-C columns from Polymer Laboratories Inc., held at 40° C.; Detector: Shodex RI-201 Differential Refractive Index (DRI) Detector; Calibration: 17 polystyrene standard materials from Polymer Laboratories Inc., fit to a 3rd order polynomial curve over the range of 3742 kg/mol to 0.58 kg/mol.

Nuclear Magnetic Resonance (NMR)

¹H-NMR spectra (500 MHZ or 400 MHZ) were obtained on a Varian VNMRS-500 or VNMRS-400 spectrometer at 30° C. The chemical shifts are referenced to tetramethyl silane (TMS) (6:000) in CDCl₃.

Liquid Chromatography-Mass Spectrometry (LC/MS)

Routine liquid chromatography/mass spectrometry (LC/MS) studies were carried out as follows. One microliter aliquots of the sample, as “1 mg/ml solution in tetrahydrofuran (THF),” are injected on an Agilent 1200SL binary liquid chromatography (LC), coupled to an Agilent 6520 quadruple time-of-flight (Q-TOF) MS system, via a dual electrospray interface (ESI), operating in the PI mode. The following analysis conditions are used: Column: Agilent Eclipse XDB-C18, 4.6*50 mm, 1.7 um; Column oven temperature: 30° C.; Solvent A: THF; Solvent B: 0.1% formic acid in water/Acetonitrile (v/v, 95/5); Gradient: 40-80% Solvent A in 0-6 min, and held for 9 min; Flow: 0.3 mL/min; UV detector: diode array, 254 nm; MS condition: Capillary Voltage: 3900 kV (Neg), 3500 kV (Pos); Mode: Neg and Pos; Scan: 100-2000 amu; Rate: is/scan; Desolvation temperature: 300° C.

Synthesis of Monomer A1 and Monomer A2

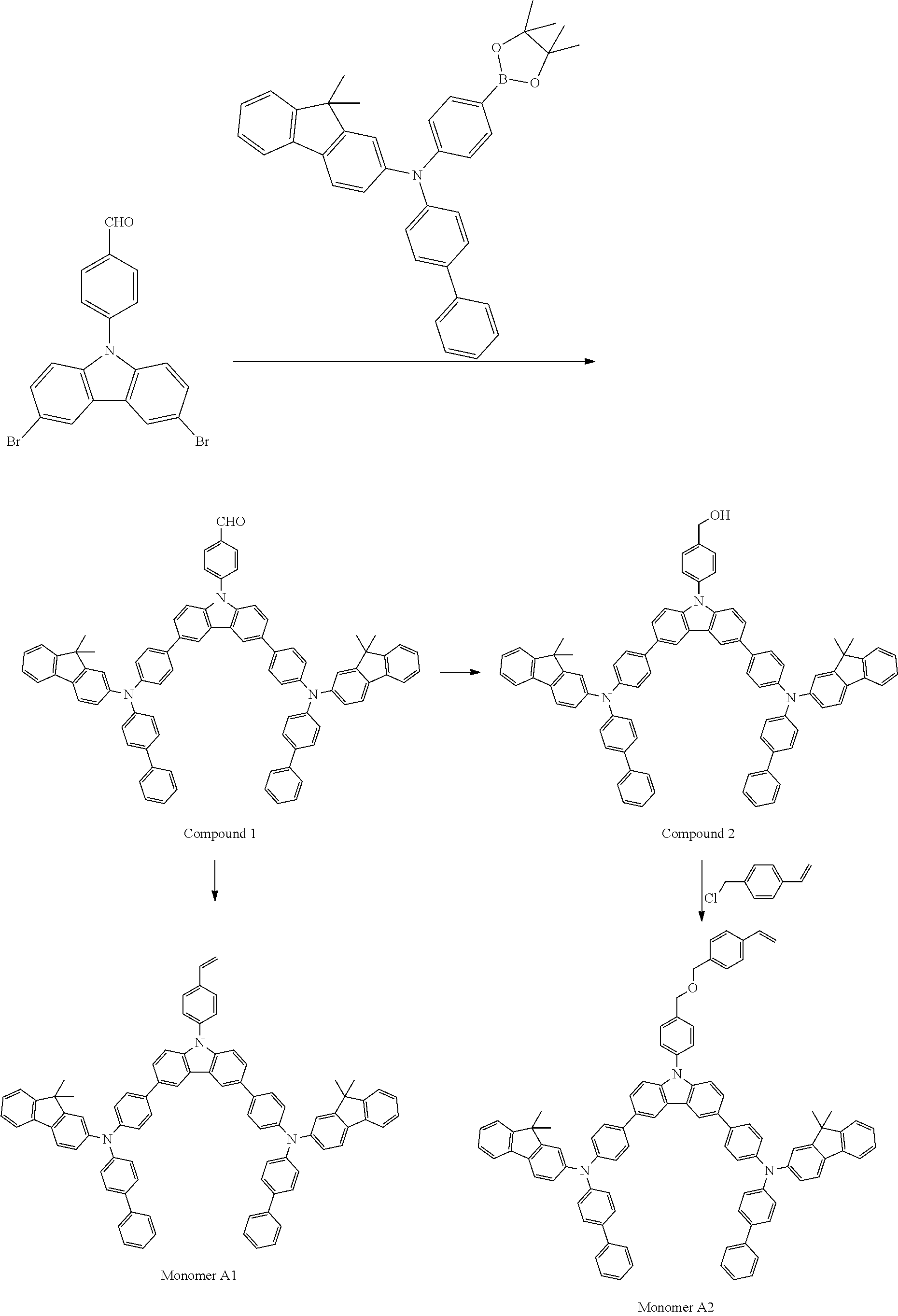

### Synthesis of 4-(3,6-bis(4-([1,1′-biphenyl]-4-yl(9,9-dimethyl-9H-fluoren-2-yl)amino)phenyl)-9H-carbazol-9-yl)benzaldehyde (Compound 1)

A mixture of 4-(3,6-dibromo-9H-carbazol-9-yl)benzaldehyde (6.00 g, 17.74 mmol), N-([1,1′-biphenyl]-4-yl)-9,9-dimethyl-N-(4-(4,4,5,5-tetramethyl-1,3,2-dioxaborolan-2-yl)phenyl)-9H-fluoren-2-amine (15.70 g, 35.49 mmol), Pd(PPh₃)₃(0.96 g), 7.72 g K₂CO₃, 100 mL THF and 30 mL H₂O was heated at 80° C. under nitrogen overnight. After cooled to room temperature, the solvent was removed under vacuum and the residue was extracted with dichloromethane. The product was then obtained by column chromatography on silica gel with petroleum ether and dichloromethane as eluent, to provide desired product (14.8 g, yield 92%). ¹H NMR (CDCl₃, ppm): 10.14 (s, 1H), 8.41 (d, 2H), 8.18 (d, 2H), 7.86 (d, 2H), 7.71 (dd, 2H), 7.56-7.68 (m, 14H), 7.53 (m, 4H), 7.42 (m, 4H), 7.26-735 (m, 18H), 7.13-7.17 (d, 2H), 1.46 (s, 12H).

### Synthesis of (4-(3,6-bis(4-([1,1′-biphenyl]-4-yl(9,9-dimethyl-9H-fluoren-2-yl)amino)phenyl)-9H-carbazol-9-yl)phenyl)methanol (Compound 2)

4-(3,6-bis(4-([1,1′-biphenyl]-4-yl(9,9-dimethyl-9H-fluoren-2-yl)amino)phenyl)-9H-carbazol-9-yl)benzaldehyde (10.0 g, 8.75 mmol) was dissolved into 80 mL THF and 30 mL ethanol. NaBH₄ (1.32 g, 35.01 mmol) was added under nitrogen atmosphere over 2 hours. Then, aqueous hydrochloric acid solution was added until pH 5 and the mixture was kept stirring for 30 min. The solvent was removed under vacuum and the residue was extracted with dichloromethane. The product was then dried under vacuum and used for the next step without further purification.

Synthesis of Monomer A1

Under N₂ atmosphere, PPh₃CMeBr (1.45 g, 4.00 mmol) was charged into a three-neck round-bottom flask equipped with a stirrer, to which 180 mL anhydrous THF was added. The suspension was placed in an ice bath. Then t-BuOK (0.70 g, 6.20 mmol) was added slowly to the solution, the reaction mixture turned into bright yellow. The reaction was allowed to react for an additional 3 h. After that, 4-(3,6-bis(4-([1,1′-biphenyl]-4-yl(9,9-dimethyl-9H-fluoren-2-yl)amino)phenyl)-9H-carbazol-9-yl)benzaldehyde (2.0 g, 1.75 mmol) was charged into the flask and stirred at room temperature overnight. The mixture was quenched with 2N HCl, and extracted with dichloromethane, and the organic layer was washed with deionized water three times and dried over anhydrous Na₂SO₄. The filtrate was concentrated and purified on silica gel column using dichloromethane and petroleum ether (1:3) as eluent. The crude product was further recrystallized from dichloromethane and ethyl acetate with purity of 99.8%. ESI-MS (m/z, Ion): 1140.523, (M+H)⁺. ¹H NMR (CDCl₃, ppm): 8.41 (s, 2H), 7.56-7.72 (m, 18H), 7.47-7.56 (m, 6H), 7.37-7.46 (m, 6H), 7.23-7.36 (m, 18H), 6.85 (q, 1H), 5.88 (d, 1H), 5.38 (d, 1H), 1.46 (s, 12H).

Synthesis of Monomer A2

0.45 g 60% NaH was added to 100 mL dried DMF solution of 10.00 g of (4-(3,6-bis(4-([1,1′-biphenyl]-4-yl(9,9-dimethyl-9H-fluoren-2-yl)amino)phenyl)-9H-carbazol-9-yl)phenyl)methanol. After stirred at room temperature for 1 h, 2.00 g of 1-(chloromethyl)-4-vinylbenzene was added by syringe. The solution was stirred at 60° C. under N₂ and tracked by TLC. After the consumption of the starting material, the solution was cooled and poured into ice water. After filtration and washed with water, ethanol and petroleum ether respectively, the crude product was obtained and dried in vacuum oven at 50° C. overnight and then purified by flash silica column chromatography with grads evolution of the eluent of dichloromethane and petroleum ether (1:3 to 1:1). The crude product was further purified by recrystallization from ethyl acetate and column chromatography which enabled the purity of 99.8%. ESI-MS (m/z, Ion): 1260.5811, (M+H)+. ¹H NMR (CDCl₃, ppm): 8.41 (s, 2H), 7.58-7.72 (m, 18H), 7.53 (d, 4H), 7.38-7.50 (m, 12H), 7.25-7.35 (m, 16H), 7.14 (d, 2H), 6.75 (q, 1H), 5.78 (d, 1H), 5.26 (d, 1H), 4.68 (s, 4H), 1.45 (s, 12H).

### Preparation of Homopolymer of Monomer A1 (Example 1)

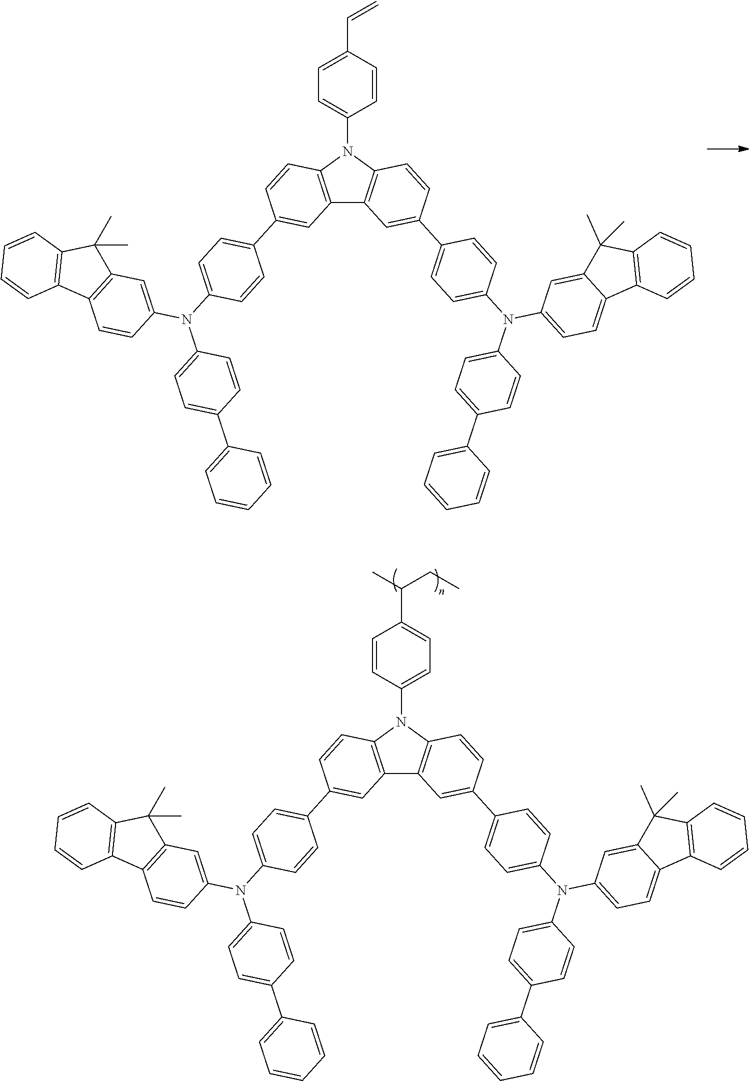

4 mg/mL AIBN anisole solution was firstly prepared in glove-box. A1 monomer (300 mg, 0.26 mmol) and 0.32 mL 4 mg/mL AIBN anisole solution (3 mol %) were added into 0.68 mL anisole in seal tube in glove-box. Then the mixture was stirred overnight at 70° C. After cooled to room temperature, the seal tube was put into glove-box, then 8 mg/mL AIBN anisole solution was freshly prepared, 0.1 mL of which was added and stirred overnight at 70° C., which ensure the full conversion. Precipitation was observed after 24 hrs. 0.5 mL anisole was added to dissolve the precipitation in reaction. Then precipitated with methanol, solid content was dissolved into 4 mL anisole (heat was needed to ensure the dissolution), and precipitated with 10 mL methanol. Precipitation was repeated 2 times. The obtained white solid was dried in vacuum oven at 100° C. over 10 hrs. The resulted homopolymer of Monomer A1 has a Mₙ of 15,704, an M_{w} of 61,072, an M_{z} of 124,671, an M_{z}+₁ of 227,977, and a PDI of 3.89.

### Preparation of Homopolymer of Monomer A2 (Example 2)

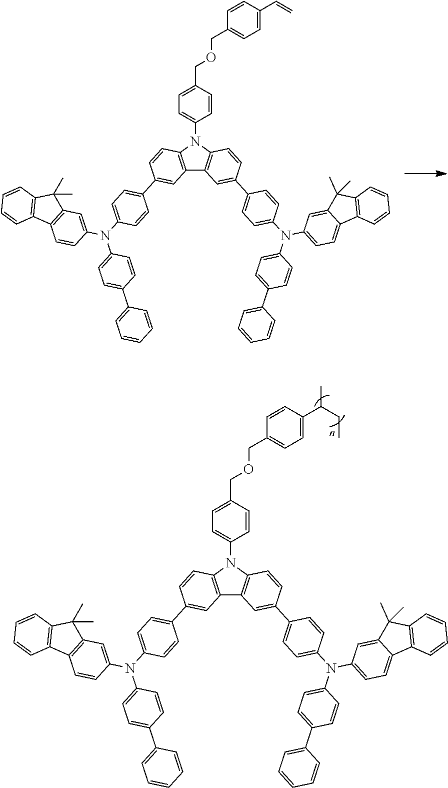

4 mg/mL AIBN anisole solution was firstly prepared in glove-box. A2 monomer (600 mg, 0.48 mmol) and 0.60 mL 4 mg/mL AIBN anisole solution (3 mol %) were added into 1.0 mL anisole in seal tube in glove-box. Then the mixture was stirred overnight at 70° C. ¹H NMR was checked, which shows very poor signal from unreacted vinyl group. 8 mg/mL AIBN anisole solution was freshly prepared. 0.3 mL was added and stirred overnight at 70° C., which ensure the full conversion. After precipitation with methanol, solid content was dissolved into 6 mL anisole (heat was needed to ensure the dissolution), and precipitated with 15 mL methanol. Precipitation was repeated 2 times. The obtained white solid was dried in vacuum oven at 100° C. over 10 hrs. The resulted homopolymer of Monomer A2 has a Mₙ of 21,482, an M_{w} of 67,058, an M_{z} of 132,385, an M_{z+1} of 226,405, and a PDI of 3.12.

Synthesis of Monomer B1

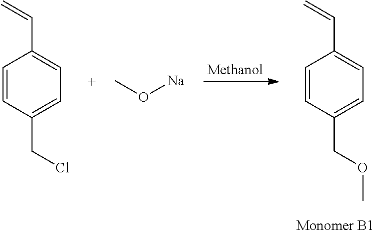

To a MeOH solution (20 mL) of 4-vinylbenzyl chloride (3.00 g, 19.66 mmol) sodium methoxide (2.68 g, 39.31 mmol) was added. The reaction mixture was heated to reflux for 24 h. After cooling to room temperature, it was then filtered and concentrated in vacuo. The crude product was diluted with diethyl ether (30 mL) and then washed with water (3*30 mL). The organic layer was dried over Na₂SO₄, filtered and concentrated in vacuo. The crude product was purified by silica gel chromatography (5% EtOAc/hexane) to afford as 1-(methoxmethyl)4-vinylbenze a colorless liquid. ¹H NMR (CDCl₃, ppm): 7.38 (d, 2H), 7.28 (d, 2H), 6.70 (dd, 1H), 5.73 (d, 1H), 5.22 (d, 1H), 4.42 (s, 2H), 3.36 (s, 3H).

Preparation of Copolymer of Monomer A1 and Monomer B1

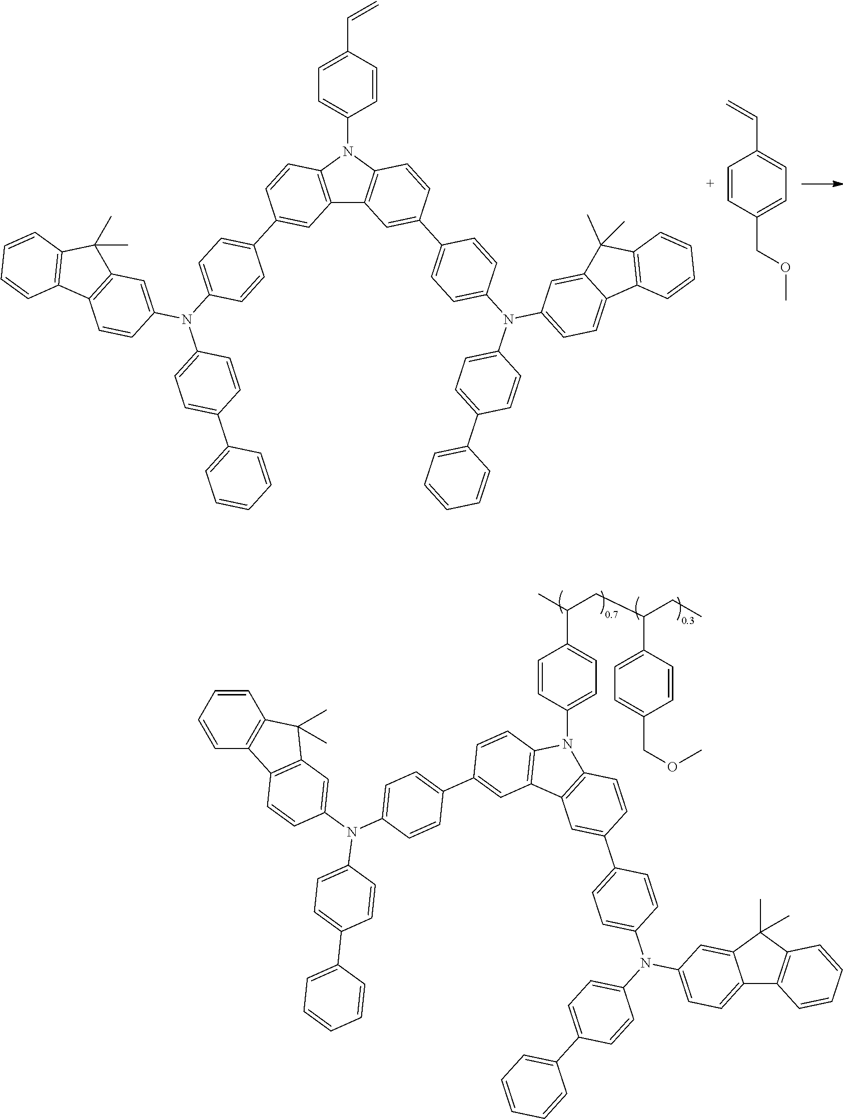

4 mg/mL AIBN anisole solution was firstly prepared in glove-box. A1 monomer (593 mg, 0.52 mmol), 1-(methoxymethyl)-4-vinylbenzene (33 mg, 0.22 mmol) and 0.65 mL 4 mg/mL AIBN anisole solution were added into 1.1 mL anisole in seal tube in glove-box. The mixture was stirred overnight at 70° C. 1H NMR was checked, which shows very poor signal from unreacted vinyl group. 8 mg/mL AIBN anisole solution was freshly prepared, 0.2 mL of which was added and stirred overnight at 70° C., which ensure the full conversion. After precipitation with methanol, solid content was dissolved into 6 mL anisole (heat was needed to ensure the dissolution), and precipitated with 12 mL methanol. Precipitation was repeated 2 times. The obtained white solid was dried in vacuum oven at 100° C. over 10 hrs. The resulted copolymer of Monomer A1 and Monomer B1 has an Mₙ of 11,951, an M_{w} of 48,474, an M_{z} of 140,533, an M_{z}+₁ of 248,932, and a PDI of 4.06.

### Synthesis of Comparative Monomer: N-([1,1′-biphenyl]-4-yl)-9,9-dimethyl-N-(4-(9-(4-(((4-vinylbenzyl)oxy)methyl)phenyl)-9H-carbazol-3-yl)phenyl)-9H-fluoren-2-amine (CAS: 1883576-19-9)

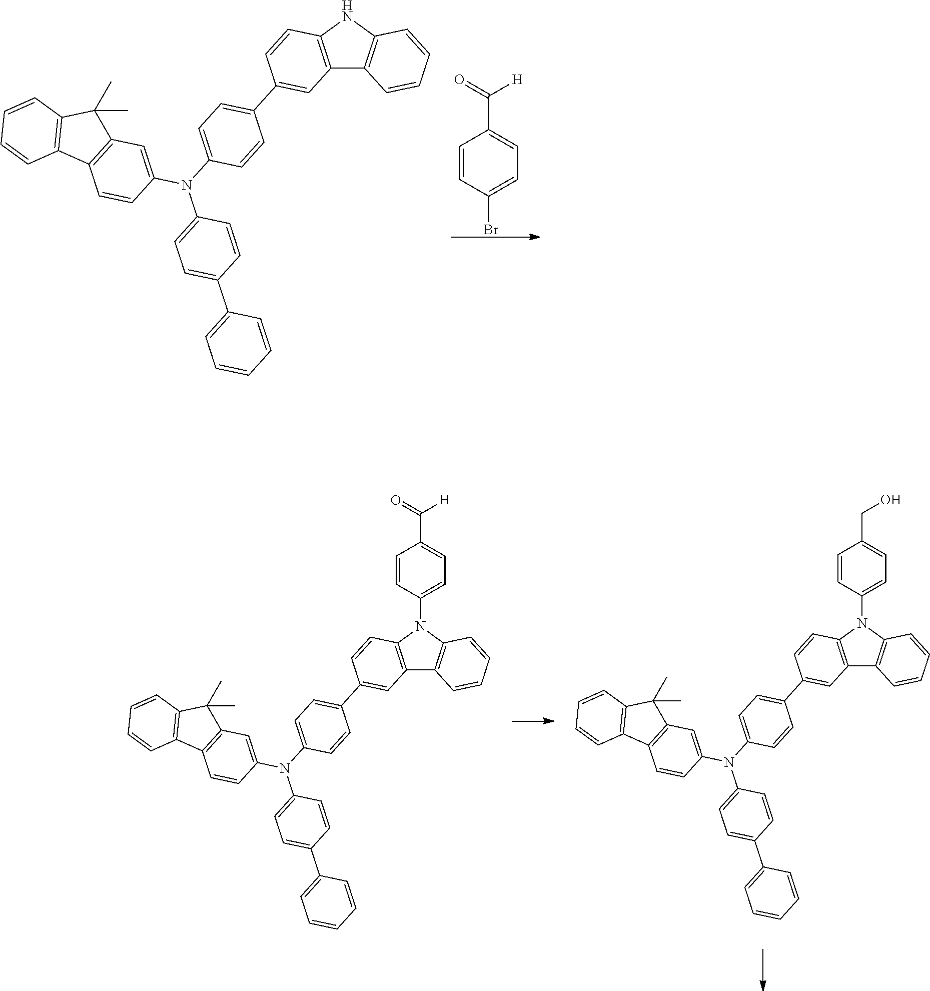 [SMILES: CC1(C)c2ccccc2-c2ccc(N(c3ccc(-c4ccccc4)cc3)c3ccc(-c4ccc5[nH]c6ccccc6c5c4)cc3)cc21 ; O=Cc1ccc(Br)cc1 ; CC1(C)c2ccccc2-c2ccc(N(c3ccc(-c4ccccc4)cc3)c3ccc(-c4ccc5c(c4)c4ccccc4n5-c4ccc(C=O)cc4)cc3)cc21 ; CC1(C)c2ccccc2-c2ccc(N(c3ccc(-c4ccccc4)cc3)c3ccc(-c4ccc5c(c4)c4ccccc4n5-c4ccc(CO)cc4)cc3)cc21]

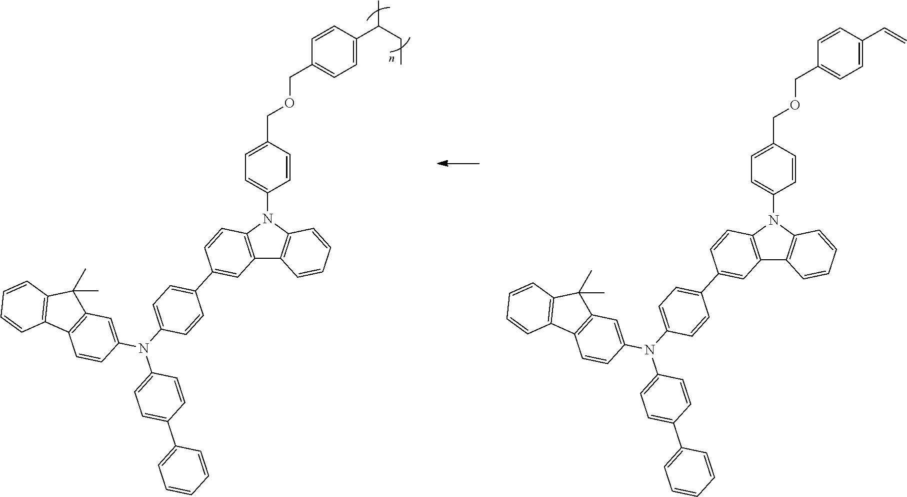

### Synthesis of 4-(3-(4-([1,1′-biphenyl]-4-yl(9,9-dimethyl-9H-fluoren-2-yl)amino)phenyl)-9H-carbazol-9-yl)benzaldehyde

A round-bottom flask was charged with N-(4-(9H-carbazol-3-yl)phenyl)-N-([1,1′-biphenyl]-4-yl)-9,9-dimethyl-9H-fluoren-2-amine (2.00 g, 3.32 mmol, 1.0 equiv), 4-bromobenzaldehyde (0.74 g, 3.98 mmol, 1.2 equiv), CuI (0.13 g, 0.66 mmol, 0.2 equiv), potassium carbonate (1.38 g, 9.95 mmol, 3.0 equiv), and 18-crown-6 (86 mg, 10 mol %). The flask was flushed with nitrogen and connected to a reflux condenser. 10.0 mL dry, degassed 1,2-dichlorobenzene was added, and the mixture was refluxed for 48 hours. The cooled solution was quenched with sat. aq. NH₄Cl, and extracted with dichloromethane. Combined organic fractions were dried, and solvent was removed by distillation. The crude residue was purified by chromatography on silica gel (hexane/chloroform gradient), and gave a bright yellow solid product (2.04 g). The product had the following characteristics: ¹H-NMR (CDCl₃, ppm): 10.13 (s, 1H), 8.37 (d, J=2.0 Hz, 1H), 8.20 (dd, J=7.7, 1.0 Hz, 1H), 8.16 (d, J=8.2 Hz, 2H), 7.83 (d, J=8.1 Hz, 2H), 7.73-7.59 (m, 7H), 7.59-7.50 (m, 4H), 7.50-7.39 (m, 4H), 7.39-7.24 (m, 10H), 7.19-7.12 (m, 1H), 1.47 (s, 6H).

### Synthesis of (4-(3-(4-([1,1′-biphenyl]-4-yl(9,9-dimethyl-9H-fluoren-2-yl)amino)phenyl)-9H-carbazol-9-yl)phenyl)methanol

A round-bottom flask was charged with 4-(3-(4-([1,1′-biphenyl]-4-yl(9,9-dimethyl-9H-fluoren-2-yl)amino)phenyl)-9H-carbazol-9-yl)benzaldehyde (4.36 g, 6.17 mmol, 1.00 equiv) under a blanket of nitrogen. The material was dissolved in 40 mL 1:1 THF:EtOH. borohydride (0.28 g, 7.41 mmol, 1.20 equiv) was added in portions and the material was stirred for 3 hours. The reaction mixture was cautiously quenched with 1M HCl, and the product was extracted with portions of dichloromethane. Combined organic fractions were washed with sat. aq. sodium bicarbonate, dried with MgSO₄ and concentrated to a crude residue. The material was purified by chromatography (hexane/dichloromethane gradient), and gave a white solid product (3.79 g). The product had the following characteristics: ¹H-NMR (CDCl₃, ppm): 8.35 (s, 1H), 8.19 (dt, J=7.8, 1.1 Hz, 1H), 7.73-7.56 (m, 11H), 7.57-7.48 (m, 2H), 7.48-7.37 (m, 6H), 7.36-7.23 (m, 9H), 7.14 (s, 1H), 4.84 (s, 2H), 1.45 (s, 6H).

### Synthesis of N-([1,1′-biphenyl]-4-yl)-9,9-dimethyl-N-(4-(9-(4-(((4-vinylbenzyl)oxy)methyl)phenyl)-9H-carbazol-3-yl)phenyl)-9H-fluoren-2-amine

In a nitrogen-filled glovebox, a 100 mL round-bottom flask was charged with Formula 2 (4.40 g, 6.21 mmol, 1.00 equiv) and 35 mL THF. Sodium hydride (0.22 g, 9.32 mmol, 1.50 equiv) was added in portions, and the mixture was stirred for 30 minutes. A reflux condenser was attached, the unit was sealed and removed from the glovebox. 4-vinylbenzyl chloride (1.05 mL, 7.45 mmol, 1.20 equiv) was injected, and the mixture was refluxed until consumption of starting material. The reaction mixture was cooled (iced bath) and cautiously quenched with isopropanol. Sat. aq. NH₄Cl was added, and the product was extracted with ethyl acetate. Combined organic fractions were washed with brine, dried with MgSO₄, filtered, concentrated, and purified by chromatography on silica. The product had the following characteristics: ¹H-NMR (CDCl₃, ppm): 8.35 (s, 1H), 8.18 (dt, J=7.8, 1.0 Hz, 1H), 7.74-7.47 (m, 14H), 7.47-7.35 (m, 11H), 7.35-7.23 (m, 9H), 7.14 (s, 1H), 6.73 (dd, J=17.6, 10.9 Hz, 1H), 5.76 (dd, J=17.6, 0.9 Hz, 1H), 5.25 (dd, J=10.9, 0.9 Hz, 1H), 4.65 (s, 4H), 1.45 (s, 6H).

### Preparation of homopolymer of N-([1,1′-biphenyl]-4-yl)-9,9-dimethyl-N-(4-(9-(4-(((4-vinylbenzyl)oxy)methyl)phenyl)-9H-carbazol-3-yl)phenyl)-9H-fluoren-2-amine (Comparative Example)

In a glovebox, N-([1,1′-biphenyl]-4-yl)-9,9-dimethyl-N-(4-(9-(4-(((4-vinylbenzyl)oxy)methyl)phenyl)-9H-carbazol-3-yl)phenyl)-9H-fluoren-2-amine (1.00 equiv) was dissolved in anisole (electronic grade, 0.25M). The mixture was heated to 70° C., and AIBN solution (0.20M in toluene, 5 mol %) was injected. The mixture was stirred until complete consumption of monomer, at least 24 hours (2.5 mol % portions of AIBN solution can be added to complete conversion). The polymer was precipitated with methanol (10× volume of anisole) and isolated by filtration. The filtered solid was rinsed with additional portions of methanol. The filtered solid was re-dissolved in anisole and the precipitation/filtration sequence repeated twice more. The isolated solid was placed in a vacuum oven overnight at 50° C. to remove residual solvent. The resulted homopolymer of N-([1,1′-biphenyl]-4-yl)-9,9-dimethyl-N-(4-(9-(4-(((4-vinylbenzyl)oxy)methyl)phenyl)-9H-carbazol-3-yl)phenyl)-9H-fluoren-2-amine has a Mₙ of 21,501, an M_{w} of 45,164, an M_{z} of 73,186, an M_{z+1} of 102,927, and a PDI of 2.10.

HTL Homopolymer/Copolymer Film Study

Preparation of HTL homopolymer/copolymer solution: HTL homopolymer/copolymer solid powders were directly dissolved into anisole to make a 2 wt % stock solution. The solution was stirred at 80° C. for 5 to 10 mins in N₂ for complete dissolving.

Preparation of thermally annealed HTL homopolymer/copolymer film: Si wafer was pre-treated by UV-ozone for 2 mins prior to use. Several drops of the above filtered HTL solution were deposited onto the pre-treated Si wafer. The thin film was obtained by spin coating at 500 rpm for 5 s and then 2000 rpm for 30 s. The resulting film was then transferred into the N₂ purging box. The “wet” film was prebaked at 100° C. for lmin to remove most of residual anisole. Subsequently, the film was thermally annealed at 205° C. for 10 min.

Strip test on thermally annealed HTL homopolymer/copolymer film: The “Initial” thickness of thermally annealed HTL film was measured using an M-2000D ellipsometer (J. A. Woollam Co., Inc.). Then, several drops of o-xylene were added onto the film to form a puddle. After 90 s, the o-xylene solvent was spun off at 3500 rpm for 30 s. The “Strip” thickness of the film was immediately measured using the ellipsometer. The film was then transferred into the N₂ purging box, followed by post-baking at 100° C. for lmin to remove any swollen solvent in the film. The “Final” thickness was measured using the ellipsometer. The film thickness was determined using Cauchy model and averaged over 9=3×3 points in a 1 cm×1 cm area.

“−Strip”=“Strip”−“Initial”: Initial film loss due to solvent strip

“−PSB”=“Final”−“Strip”: Further film loss of swelling solvent

“−Total”=“−Strip”+“−PSB”=“Final”−“Initial”: Total film loss due to solvent strip and swelling

Strip tests were applied for studying HTL homopolymer/copolymer orthogonal solvency. For a fully solvent resistant HTL film, the total film loss after solvent stripping should be <1 nm, preferably <0.5 nm.

A1 Homopolymer Strip Test Results

| Stripping | | | | | | |
|---|---|---|---|---|---|---|
| time | Initial | Strip | -Strip | Final | -PSB | -Total |
| (min) | (nm) | (nm) | (nm) | (nm) | (nm) | (nm) |
| 1.5 | 41.96 ± | 42.55 ± | +0.59 | 42.05 ± | −0.49 | +0.09 |
| | 0.09 | 0.05 | | 0.08 | | |
| 5 | 42.05 ± | 42.96 ± | +0.91 | 42.15 ± | −0.81 | +0.10 |
| | 0.08 | 0.06 | | 0.09 | | |

A2 Homopolymer Strip Test Results

| Stripping | | | | | | |
|---|---|---|---|---|---|---|
| time | Initial | Strip | -Strip | Final | -PSB | -Total |
| (min) | (nm) | (nm) | (nm) | (nm) | (nm) | (nm) |
| 1.5 | 40.99 ± | 41.45 ± | +0.46 | 41.04 ± | −0.41 | +0.05 |
| | 0.05 | 0.04 | | 0.11 | | |
| 5 | 30.47 ± | 30.83 ± | +0.36 | 30.25 ± | −0.58 | −0.22 |
| | 0.11 | 0.12 | | 0.14 | | |

A1B1 Copolymer Strip Test Results

| Stripping | | | | | | |
|---|---|---|---|---|---|---|
| time | Initial | Strip | -Strip | Final | -PSB | -Total |
| (min) | (nm) | (nm) | (nm) | (nm) | (nm) | (nm) |
| 1.5 | 43.05 ± | 43.22 ± | +0.21 | 42.86 ± | −0.37 | −0.16 |
| | 0.12 | 0.10 | | 0.10 | | |
| 5 | 42.86 ± | 43.40 ± | +0.54 | 42.81 ± | −0.59 | −0.04 |
| | 0.10 | 0.10 | | 0.09 | | |

For full solvent resistance, the total film loss should be <1 nm, preferably <0.50 nm. Homopolymer A1, A2, and copolymer A1B1 films are orthogonal to 1.5 and 5 mins o-xylene stripping, which enable further process of solution EML layer with reduced interlayer penetration.

OLED Device Fabrication

Glass substrates (50 mm by 50 mm) having pixelated Indium Tin Oxide (ITO) electrodes were cleaned with solvents (ethanol, acetone, isopropanol sequentially) and ultraviolet/ozone (UVO) Treatment.

Each cell containing HIL, HTL, EML, ETL and EIL, was prepared based on materials listed in Table 1.

For the HIL layer, Plexcore™ OC RG-1200 (Poly(thiophene-3-[2-(2-methoxyethoxy)ethoxy]-2,5-diyl) available from Sigma-Aldrich, a sulfonated solution filtered with 0.5 micron polytetrafluoroethylene (PTFE) syringe filter) was spin-coated (speed: 5 s 1000 rpm, 30 s 5000 rpm), inside a nitrogen filled glove-box, onto the ITO Glass substrates. The spin-coated film was annealed at 150° C. for 20 minutes. The annealed film thickness was in the range of 30-80 nm.

The HTL material solution in anisole (22 mg/mL, filtered with 0.2 micron polytetrafluoroethylene (PTFE) syringe filter) was spin-coated (speed: 5 s 2000 rpm, 30 s 4000 rpm), onto the HIL coated ITO Glass substrates and annealed (annealing condition: 205° C., 10 mins). The annealed film thickness was in the range of 10-200 nm.

For EML layer, 9-(4,6-diphenylpyrimidin-2-yl)-9′-phenyl-9H,9′H-3,3′-bicarbazole (host) and tris[3-[4-(1,1-dimethylethyl)-2-pyridinyl-xN][1,1′-biphenyl]-4-yl-KC]iridium (dopant) were mixed in o-xylene (2.0 wt %, Host:dopant (15%), filtered with 0.2 micron polytetrafluoroethylene (PTFE) syringe filter), then spin-coated (speed: 5 s 500 rpm, 30 s 2000 rpm), onto the HIL and HTL coated ITO Glass substrates and annealed at 120° C. for 10 min. The annealed film thickness was in the range of 10-200 nm. For the electron transport layer, 2,4-bis(9,9-dimethyl-9H-fluoren-2-yl)-6-(naphthalen-2-yl)-1,3,5-triazine was co-evaporated with lithium quinolate (Liq), until the thickness reached 350 Angstrom. The evaporation rate for the ETL compounds and Liq was 0.4 A/s and 0.6 A/s. Finally, “20 Angstrom” of a thin electron injection layer (Liq) was evaporated at a 0.5 A/s rate. Finally, these OLED (reported in Table 1) were hermetically sealed prior to testing.

The OLED have the following common structure: HIL (400 Å±20 Å)/HTL (200˜300 Å)/Green EML(400 Å)/ETL:Liq(350 Å)/Liq(20 Å).

TABLE 1

| | Name | CAS No. |
|---|---|---|
| HIL | Poly(thiophene-3-[2-(2-methoxyethoxy)ethoxy]-2,5-diyl), | 1003582-37-3 |
| compound | sulfonated solution | |
| HTL | Comp Ex: homopolymer of N-([1,1′-biphenyl]-4-yl)-9,9- | |
| compound | dimethyl-N-(4-(9-(4-(((4-vinylbenzyl)oxy)methyl)phenyl)- | |
| | 9H-carbazol-3-yl)phenyl)-9H-fluoren-2-amine | |
| | Ex 1: Homopolymer of Monomer A1 | |
| | Ex 2: Homopolymer of Monomer A2 | |
| Green | 9-(4,6-diphenylpyrimidin-2-yl)-9′-phenyl-9H,9′H-3,3′- | 1266389-00-7 |
| Host | bicarbazole | |
| Green | Tris[3-[4-(1,1-dimethylethyl)-2-pyridinyl-κN][1,1′- | 1528724-69-7 |
| Dopant | biphenyl]-4-yl-κC]iridium | |
| ETL | 2,4-bis(9,9-dimethyl-9H-fluoren-2-yl)-6-(naphthalen-2-yl)- | 1459162-51-6 |
| compound | 1,3,5-triazine | |
| EIL | lithium quinolate | 850918-68-2 |
| compound | | |

The current density-voltage-luminance (J-V-L) characterizations for the OLED devices were performed with a KEITHLEY 2400 Source Meter and a Photo Research PR655 Spectroradiometer.

As shown in Table 2, Inventive OLED Devices had higher luminous efficiencies compared to that of Comparative Device.

TABLE 2

| | | Driving | Efficiency |
|---|---|---|---|
| Devices | HTL Materials | Voltage (V) | (cd/A) |
| Comparative Device | Comp Ex: homopolymer of N- | 4.9 | 27.3 |
| | ([1,1′-biphenyl]-4-yl)-9,9- | | |
| | dimethyl-N-(4-(9-(4-(((4- | | |
| | vinylbenzyl)oxy)methyl)phenyl)- | | |
| | 9H-carbazol-3-yl)phenyl)-9H- | | |
| | fluoren-2-amine | | |
| Inventive Device 1 | Homopolymer of Monomer A1 | 4.9 | 30.3 |
| Inventive Device 2 | Homopolymer of Monomer A2 | 4.6 | 31.5 |

1. A polymeric charge transfer layer composition comprising a polymer comprising, as polymerized unit, at least one carbazole-based Monomer A having the following Structure A: 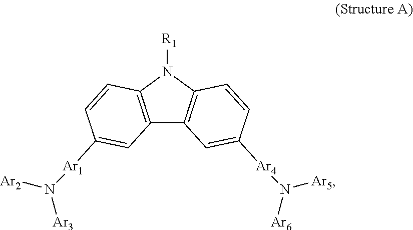
wherein Ar₁ to Ar₆ are each independently selected from a substituted or unsubstituted aromatic moiety, and a substituted or unsubstituted heteroaromatic moiety, and
R₁ is selected from the group consisting of hydrogen, deuterium, a substituted or unsubstituted hydrocarbyl, a substituted or unsubstituted heterohydrocarbyl, a halogen, a cyano, a substituted or unsubstituted aryl, and a substituted or unsubstituted heteroaryl.

2. The polymeric charge transfer layer composition according to claim 1, wherein Monomer A is present in an amount of at least 54% by mole, based on the total moles of all monomers in the polymer.

3. The polymeric charge transfer layer composition according to claim 1, wherein Monomer A is selected from the following Compounds (A1) through (A9):

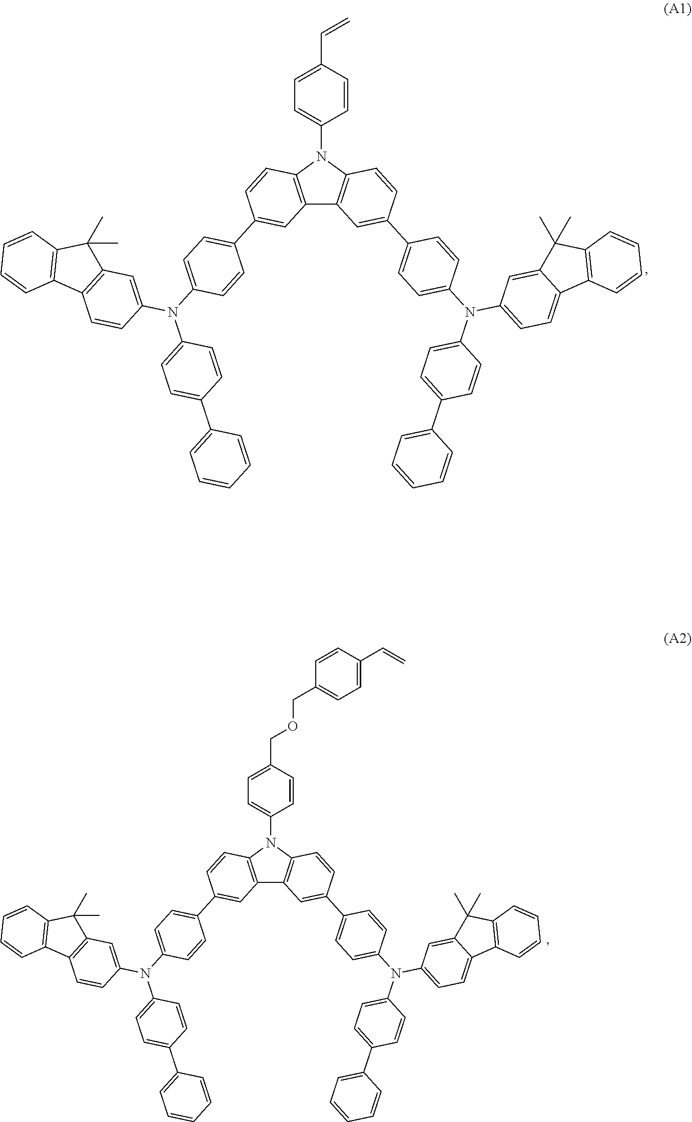 [SMILES: C=Cc1ccc(-n2c3ccc(-c4ccc(N(c5ccc(-c6ccccc6)cc5)c5ccc6c(c5)C(C)(C)c5ccccc5-6)cc4)cc3c3cc(-c4ccc(N(c5ccc(-c6ccccc6)cc5)c5ccc6c(c5)C(C)(C)c5ccccc5-6)cc4)ccc32)cc1 ; C=Cc1ccc(COCc2ccc(-n3c4ccc(-c5ccc(N(c6ccc(-c7ccccc7)cc6)c6ccc7c(c6)C(C)(C)c6ccccc6-7)cc5)cc4c4cc(-c5ccc(N(c6ccc(-c7ccccc7)cc6)c6ccc7c(c6)C(C)(C)c6ccccc6-7)cc5)ccc43)cc2)cc1]

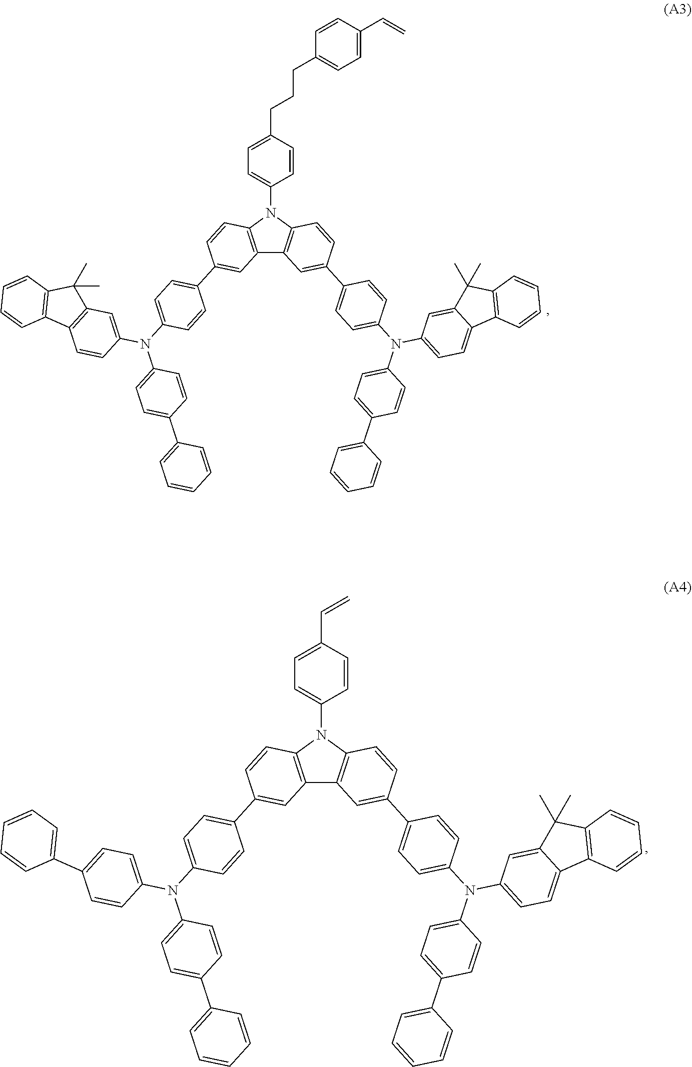 [SMILES: C=Cc1ccc(CCCc2ccc(-n3c4ccc(-c5ccc(N(c6ccc(-c7ccccc7)cc6)c6ccc7c(c6)C(C)(C)c6ccccc6-7)cc5)cc4c4cc(-c5ccc(N(c6ccc(-c7ccccc7)cc6)c6ccc7c(c6)C(C)(C)c6ccccc6-7)cc5)ccc43)cc2)cc1 ; C=Cc1ccc(-n2c3ccc(-c4ccc(N(c5ccc(-c6ccccc6)cc5)c5ccc(-c6ccccc6)cc5)cc4)cc3c3cc(-c4ccc(N(c5ccc(-c6ccccc6)cc5)c5ccc6c(c5)C(C)(C)c5ccccc5-6)cc4)ccc32)cc1]

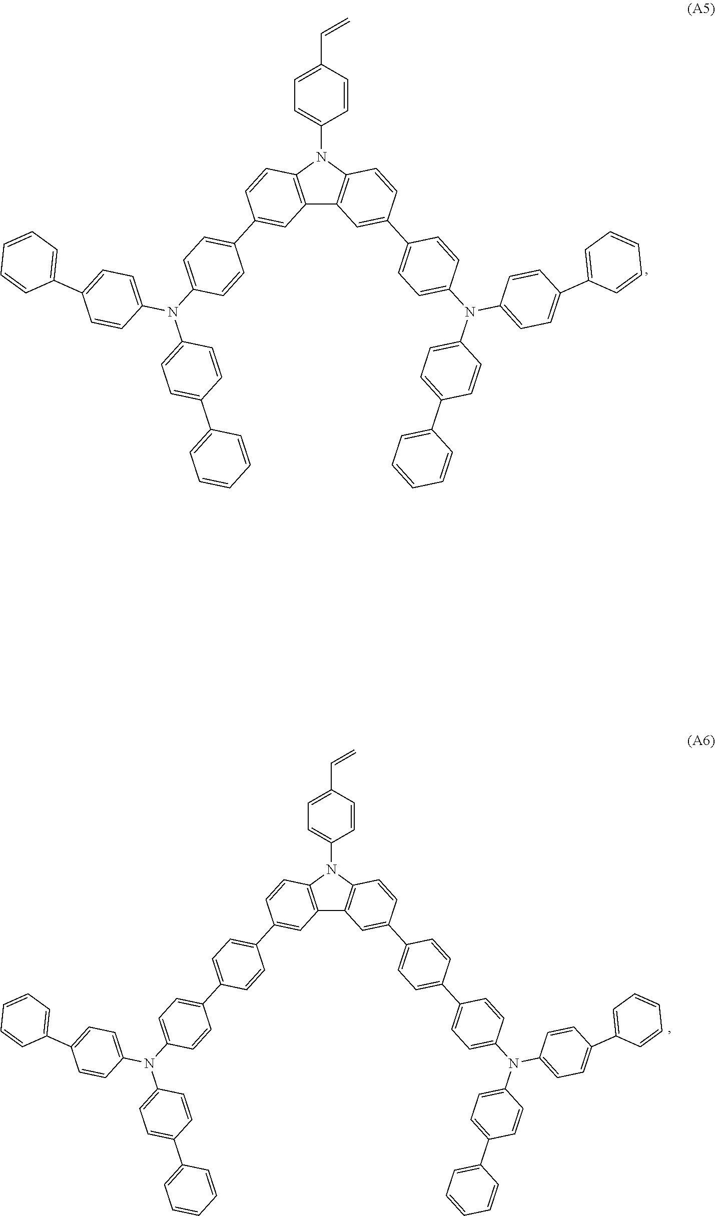 [SMILES: C=Cc1ccc(-n2c3ccc(-c4ccc(N(c5ccc(-c6ccccc6)cc5)c5ccc(-c6ccccc6)cc5)cc4)cc3c3cc(-c4ccc(N(c5ccc(-c6ccccc6)cc5)c5ccc(-c6ccccc6)cc5)cc4)ccc32)cc1 ; C=Cc1ccc(-n2c3ccc(-c4ccc(-c5ccc(N(c6ccc(-c7ccccc7)cc6)c6ccc(-c7ccccc7)cc6)cc5)cc4)cc3c3cc(-c4ccc(-c5ccc(N(c6ccc(-c7ccccc7)cc6)c6ccc(-c7ccccc7)cc6)cc5)cc4)ccc32)cc1]

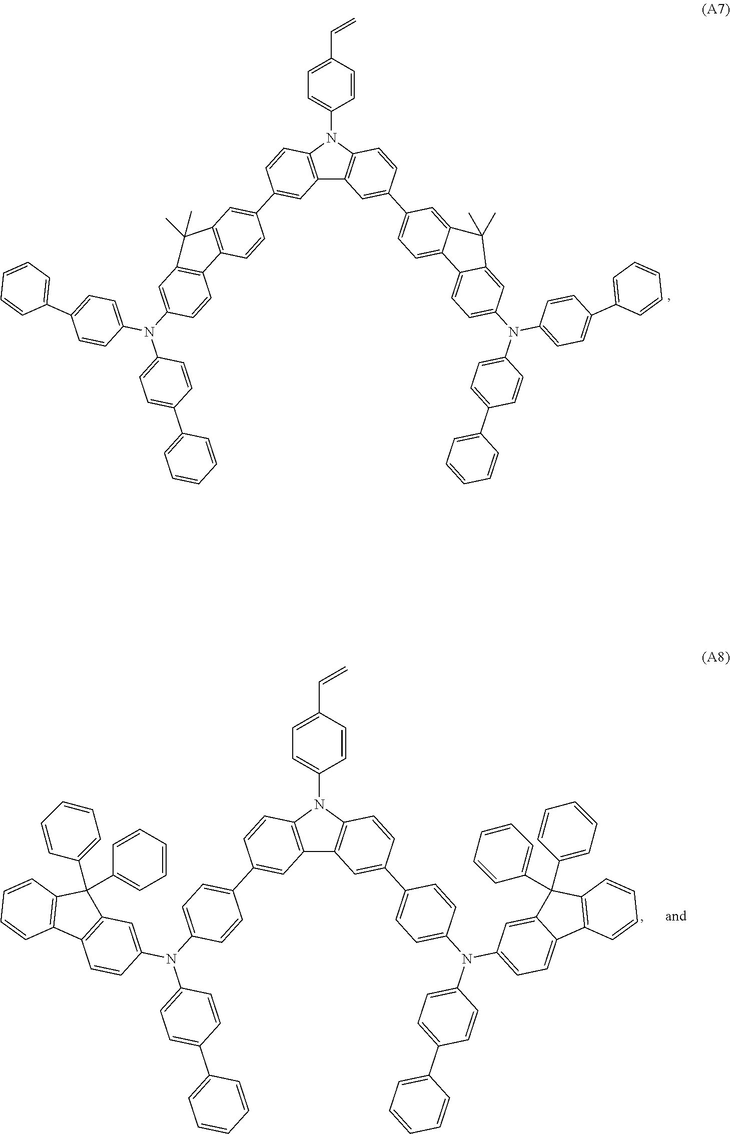 [SMILES: C=Cc1ccc(-n2c3ccc(-c4ccc5c(c4)C(C)(C)c4cc(N(c6ccc(-c7ccccc7)cc6)c6ccc(-c7ccccc7)cc6)ccc4-5)cc3c3cc(-c4ccc5c(c4)C(C)(C)c4cc(N(c6ccc(-c7ccccc7)cc6)c6ccc(-c7ccccc7)cc6)ccc4-5)ccc32)cc1 ; C=Cc1ccc(-n2c3ccc(-c4ccc(N(c5ccc(-c6ccccc6)cc5)c5ccc6c(c5)C(c5ccccc5)(c5ccccc5)c5ccccc5-6)cc4)cc3c3cc(-c4ccc(N(c5ccc(-c6ccccc6)cc5)c5ccc6c(c5)C(c5ccccc5)(c5ccccc5)c5ccccc5-6)cc4)ccc32)cc1]

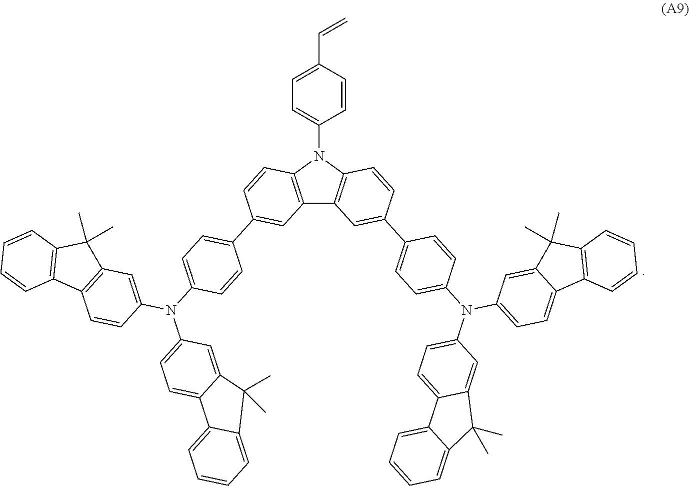 [SMILES: C=Cc1ccc(-n2c3ccc(-c4ccc(N(c5ccc6c(c5)C(C)(C)c5ccccc5-6)c5ccc6c(c5)C(C)(C)c5ccccc5-6)cc4)cc3c3cc(-c4ccc(N(c5ccc6c(c5)C(C)(C)c5ccccc5-6)c5ccc6c(c5)C(C)(C)c5ccccc5-6)cc4)ccc32)cc1]

4. The polymeric charge transfer layer composition according to claim 1 wherein the polymer further comprises, as polymerized unit, at least one Monomer B having the following Structure B:
R₂—CH₂O—R₃ (Structure B),
wherein R₂ and R₃ are each independently selected from the group consisting of hydrogen, deuterium, a substituted or unsubstituted hydrocarbyl, a substituted or unsubstituted heterohydrocarbyl, a halogen, a cyano, a substituted or unsubstituted aryl, and a substituted or unsubstituted heteroaryl.

5. The polymeric charge transfer layer composition according to claim 4, wherein Monomer B is present in an amount of at most 46% by mole, based on the total moles of all monomers in the polymer.

6. The polymeric charge transfer layer composition according to claim 4, wherein Monomer B is selected from the following Compounds (B1) through (B9):

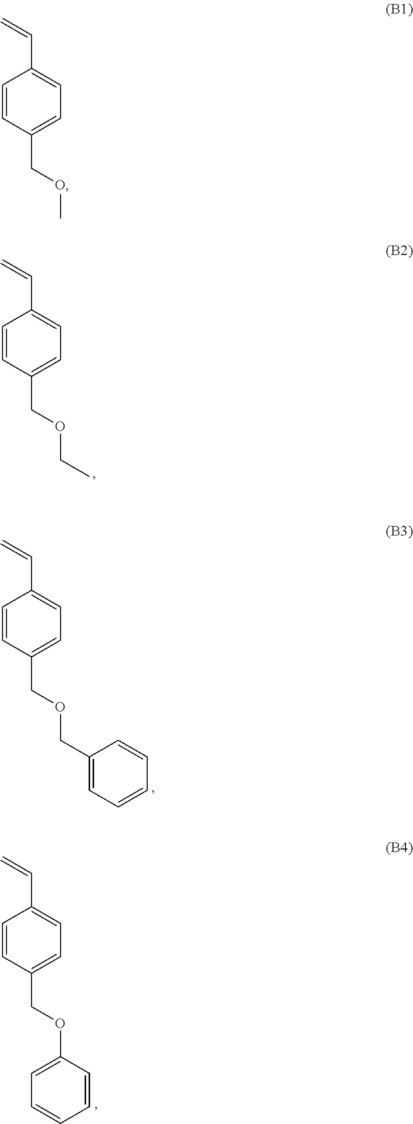 [SMILES: C=Cc1ccc(COC)cc1 ; C=Cc1ccc(COCC)cc1 ; C=Cc1ccc(COCc2ccccc2)cc1 ; C=Cc1ccc(COc2ccccc2)cc1]

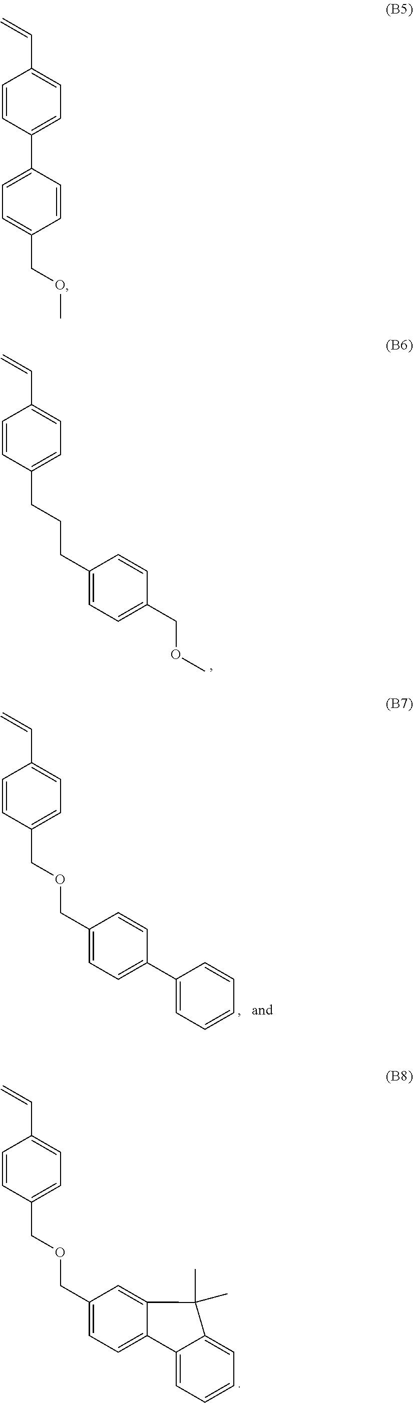 [SMILES: C=Cc1ccc(-c2ccc(COC)cc2)cc1 ; C=Cc1ccc(CCCc2ccc(COC)cc2)cc1 ; C=Cc1ccc(COCc2ccc(-c3ccccc3)cc2)cc1 ; C=Cc1ccc(COCc2ccc3c(c2)C(C)(C)c2ccccc2-3)cc1]

7. The polymeric charge transfer layer composition according to claim 1, wherein it further comprises a p-dopant selected from ionic compounds including trityl salts, ammonium salts, iodonium salts, tropylium salts, imidazolium salts, phosphonium salts, oxonium salts, and mixtures thereof.

8. The polymeric charge transfer layer composition according to claim 7, wherein the ionic compounds are selected from trityl borates, ammonium borates, iodonium borates, tropylium borates, imidazolium borates, phosphonium borates, oxonium borates, and mixtures thereof.

9. The polymeric charge transfer layer composition according to claim 7, wherein the p-dopant is the following compound (p-1):

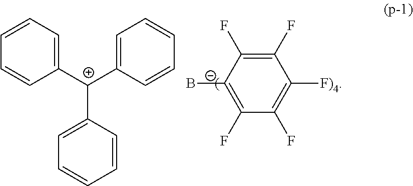

10. The polymeric charge transfer layer composition according to claim 7, wherein the p-dopant is present at an amount of from 1% to 20% by weight, based on the total weight of the polymeric charge transfer layer composition.

11. The polymeric charge transfer layer composition according to claim 1, wherein R₁ to R₃ each independently has the functional group represented by Structure I: 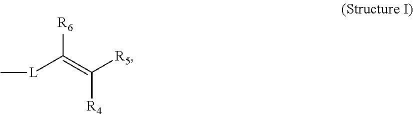
wherein R₄ to R₆ are each independently selected from the group consisting of hydrogen, deuterium, a substituted or unsubstituted C₁-C₅₀ hydrocarbyl, a substituted or unsubstituted C₁-C₅₀ heterohydrocarbyl, a halogen, a cyano, a substituted or unsubstituted C₆-C₅₀ aryl, and a substituted or unsubstituted C₄-C₅₀ heteroaryl; and
L is selected from the group consisting of a covalent bond; —O—; -alkylene-; -arylene-; -alkylene-arylene-; -arylene-alkylene-; —O-alkylene-; —O-arylene-; —O-alkylene-arylene-; —O— alkylene-O—; —O-alkylene-O-alkylene-O—; —O-arylene-O—; —O-alkylene-arylene-O—; —O—(CH₂CH₂—O)ₙ—, wherein n is an integer from 2 to 20; —O-alkylene-O-alkylene-; —O-alkylene-O-arylene-; —O-arylene-O—; —O-arylene-O-alkyene-; and —O-arylene-O-arylene.

12. The polymeric charge transfer layer composition according to claim 9, wherein L is -alkylene-, -arylene-, -alkylene-arylene-, -arylene-alkylene-, or a covalent bond.

13. An electronic device comprising the polymeric charge transfer lay composition of claim 1.

14. The electronic device of claim 13, wherein the polymeric charge transfer layer is a hole transport layer, an electron transport layer, or a hole injection layer.

15. The electronic device of claim 13, wherein the electronic device is a light emitting device.
